(19) United States
(12) Patent Application Publication
(10) Pub. No.: US 2019/0225485 A1
(43) Pub. Date: Jul. 25, 2019

(54) ENCASEMENTS FOR SENSORS

(71) Applicants: Scuba Probe Technologies LLC, Alameda, CA (US); The Regents of the University of California, Oakland, CA (US)

(72) Inventors: Dominik Ziegler, Berkeley, CA (US); Hilary Brunner, San Francisco, CA (US); Paul Ashby, Alameda, CA (US); Sina Sedighi, Berkeley, CA (US)

(73) Assignees: Scuba Probe Technologies LLC, Alameda, CA (US); The Regents of the University of California, Oakland, CA (US)

(21) Appl. No.: 16/217,157

(22) Filed: Dec. 12, 2018

Related U.S. Application Data
(60) Provisional application No. 62/597,642, filed on Dec. 12, 2017.

(51) Int. Cl. B81B 7/00; B81B 3/00

(52) U.S. Cl. CPC B81B 7/0061; B81B 2201/0271; B81B 3/0021

(57) ABSTRACT

Articles and methods involving sensors comprising encasements are generally provided. In some embodiments, a sensor comprises a mechanical resonator, a probe attached to the mechanical resonator, and an encasement encasing the mechanical resonator. The encasement encasing the mechanical resonator may comprise a first opening through which the probe protrudes and a second opening.

### RELATED APPLICATIONS

This application claims priority under 35 U.S.C. § 119(e) to U.S. Provisional Patent Application No. 62/597,642, filed Dec. 12, 2017, which is hereby incorporated by reference in its entirety.

### GOVERNMENT SPONSORSHIP

This invention was made with government support under contracts No. DE-AC02-05CH11231 and DE-SC0013212 awarded by the U.S. Department of Energy and Grant No. 1556128 awarded by the National Science Foundation. The government has certain rights in this invention.

### FIELD

Articles and methods involving sensors comprising encasements are generally provided.

### SUMMARY

Articles and methods involving sensors comprising encasements are generally provided. The subject matter disclosed herein involves, in some cases, interrelated products, alternative solutions to a particular problem, and/or a plurality of different uses of one or more systems and/or articles.

Certain articles provided herein are directed to sensors. In some embodiment, a sensor comprises a mechanical resonator, a probe attached to the mechanical resonator and an encasement encasing the mechanical resonator. The encasement may comprise a first opening through which the probe protrudes and a second opening.

Other advantages and novel features of the present invention will become apparent from the following detailed description of various non-limiting embodiments of the invention when considered in conjunction with the accompanying figures. In cases where the present specification and a document incorporated by reference include conflicting and/or inconsistent disclosure, the present specification shall control. If two or more documents incorporated by reference include conflicting and/or inconsistent disclosure with respect to each other, then the document having the later effective date shall control.

### BRIEF DESCRIPTION OF THE DRAWINGS

Non-limiting embodiments of the present invention will be described by way of example with reference to the accompanying figures, which are schematic and are not intended to be drawn to scale. In the figures, each identical or nearly identical component illustrated is typically represented by a single numeral. For purposes of clarity, not every component is labeled in every figure, nor is every component of each embodiment of the invention shown where illustration is not necessary to allow those of ordinary skill in the art to understand the invention. In the figures:

FIGS. 1A-1C are schematic depictions of sensors comprising encasements including more than one opening, according to some embodiments;

FIGS. 2A-2J are schematic depictions of sensors comprising chips, mechanical resonators, and probes, according to some embodiments;

FIGS. 3A-3B are schematic depictions of sensors comprising chips comprising reservoirs, according to some embodiments;

FIG. 4A shows the quality factor and the frequency as a function of time for a sensor comprising an encasement including more than one opening; and

FIG. 4B shows the quality factor and the frequency as a function of time for a sensor comprising an encasement including a single opening.

### DETAILED DESCRIPTION

Articles and methods related to sensors comprising encasements are generally provided. In some embodiments, the encasement may encase one or more portions of the sensor. Advantageously, the encasement may at least partially protect the encased portion(s) of the sensor from an environment in which the sensor is placed. The encasement may, in certain cases, permit the sensor to operate in an environment that would otherwise degrade its properties in a manner consistent with how it would operate when not in that environment.

Certain embodiments relate to designs for encasements that are particularly advantageous. In some embodiments, the encasement comprises two or more openings that allow access of one or more portions of the sensor to an environment exterior to the encasement. As an example, the encasement may comprise an opening through which a probe may protrude. Additionally, in some embodiments, the encasement comprises one or more openings that may be positioned and/or sized to improve the barrier properties of the encasement. As an example, the encasement may comprise one or more openings that are configured to maintain an environment inside the encasement relatively constant (e.g., an environment encased by the encasement, such as an environment encased by a hollow encasement). For instance, the encasement may comprise one or more openings that are configured to maintain a substantially constant amount of a first fluid inside the encasement (e.g., a gas initially present inside the encasement, a gas inside the encasement that enhances one or more properties of the sensor portion(s) therein, etc.). As another example, the encasement may comprise one or more openings configured to reduce intrusion into the encasement of one or more components of an environment external to the encasement. For instance, the encasement may comprise one or more openings that are configured to reduce the intrusion into the encasement of a second fluid different from the first fluid outside the encasement (e.g., a liquid such as water) and/or reduce the intrusion into the encasement of a gaseous species outside that may condense as a liquid inside the encasement. Each opening described herein should be understood to possibly provide all, some, or none of the benefits described above.

In some, but not necessarily all, embodiments, sensors described herein may be suitable for use as atomic force microscopy probes. The sensors may be configured to image samples in non-traditional atomic force microscopy environments (e.g., samples submerged under water) with stabilities and/or at qualities at or near traditional atomic force microscopy probes in air.

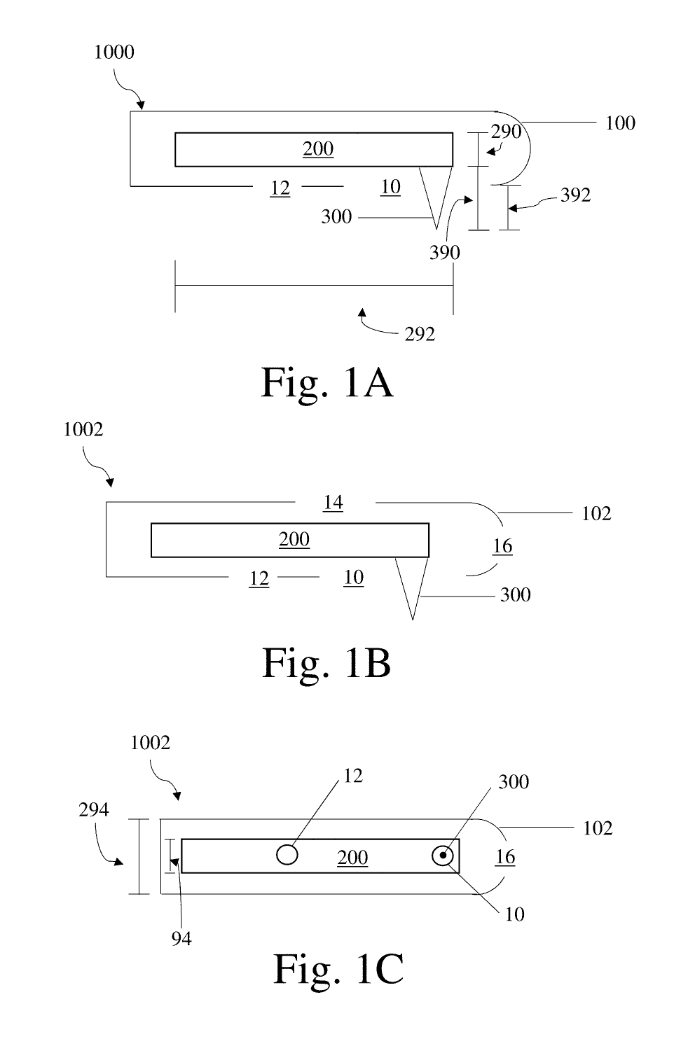

In some embodiments, a sensor as described herein may comprise a mechanical resonator, a probe, and an encasement comprising two or more openings. The encasement may encase one or more portions of the sensor (e.g., the mechanical resonator) by surrounding the encased portion(s) and/or reducing intrusion into the encasement of one or more species outside the encasement. FIG. 1A shows a non-limiting example of a sensor 1000 comprising an encasement 100 comprising a first opening 10 and a second opening 12, a mechanical resonator 200, and a probe 300 attached to mechanical resonator 200. Mechanical resonator 200 has a thickness 290 and a length 292; probe 300 has a height 390. In FIG. 1A, the encasement encases the mechanical resonator and the probe protrudes through the first opening in the encasement for a distance 392. The mechanical resonator may be centered in the encasement in some embodiments (e.g., as is shown in FIG. 1A); in other embodiments, it may not (e.g., it may be closer to the bottom surface of the encasement than the top surface of the encasement). In certain embodiments, the mechanical resonator may be a beam (e.g., like the beam shown in FIG. 1A). In some embodiments, the second opening may be in fluid communication with the first opening, such as in fluid communication with the first opening along a pathway that passes through the volume enclosed by the encasement and/or along a pathway that is encased by the encasement. As described in more detail below, in some embodiments the size (e.g., area, largest cross-sectional dimension) of the first opening is smaller than the size (e.g., area, largest cross-sectional dimension) of one or more additional openings (e.g., the second opening) present in the encasement. In some embodiments, the size (e.g., area, largest cross-sectional dimension) of the first opening is larger than the size (e.g., area, largest cross-sectional dimension) of one or more additional openings (e.g., the second opening) present in the encasement.

In some embodiments, an encasement as described herein may comprise more than two openings. For example, in some embodiments the encasement may comprise three openings, four openings, five openings, six openings, seven openings, eight openings, or even more openings. In some embodiments, the encasement may comprise as many as one hundred openings. FIG. 1B shows a non-limiting example of a sensor comprising an encasement with more than two openings. In FIG. 1B, sensor 1002 comprises encasement 102 comprising first opening 10, second opening 12, a third opening 14, and a fourth opening 16; mechanical resonator 200; and probe 300. In this exemplary figure, the first opening and second opening are both on the bottom surface of the encasement; the third opening is on the top surface of the encasement; and the fourth opening is on the front surface of the encasement (e.g., the surface of the encasement closest to the probe and/or encasing the probe). FIG. 1C shows a bottom view of the encasement shown in FIG. 1B, and shows the width 294 of the encasement. In FIG. 1C, opening 14 is not shown because it is on the top surface of the encasement.

The sensor may comprise any subset of the openings shown in FIGS. 1B-1C, all of the openings shown in FIGS. 1B-1C, and/or additional openings not shown in FIG. 1B or 1C. In some embodiments, a subset of the openings positioned on the encasement (e.g., the opening through which the probe protrudes and a second opening positioned on the encasement, two or more openings positioned on the encasement, each opening on the encasement) may be in fluid communication each other, such as in fluid communication with each other along a pathway that passes through the volume enclosed by the encasement and/or along a pathway that is encased by the encasement.

It should be understood that the relative sizes, shapes and positions of the openings shown in FIGS. 1A-1C (e.g., in relation to each other, in relation to the encasement, in relation to the mechanical resonator, in relation to the probe) are non-limiting and that certain embodiments may relate to sensors with openings of different relative sizes, shapes and positions than those shown in FIG. 1A-1C. It should also be understood that the arrangement of the openings in the encasement may be different than those shown in FIGS. 1A-1C. For example, in some embodiments an encasement may comprise an opening through which a probe protrudes that is not on the bottom surface of the encasement (e.g., it may be positioned on the top surface of the encasement, the front surface of the encasement, the back surface of the encasement, or a side surface of the encasement).

An encasement may comprise one or more additional openings (e.g., opening(s) other than those through which a probe protrudes) positioned on any suitable surface. In some embodiments, the encasement may comprise one or more openings on the same surface of the encasement as an opening through which a probe protrudes, and/or may comprise one or more openings on a different surface of the encasement than the opening through which a probe protrudes. The encasement may comprise one or more openings on a top surface of the encasement, one or more openings on a bottom surface of the encasement, one or more openings on a side surface of the encasement, one or more openings on a front surface of the encasement, one or more openings on a surface of the encasement proximate the probe, one or more surfaces on a back surface of the encasement, and/or one or more openings on a surface of the encasement distal to the probe.

In some embodiments, such as is shown in FIGS. 1A-1C, an encasement may comprise one or more openings positioned proximate to a portion of a mechanical resonator. The encasement may comprise one or more openings positioned beneath a portion of the mechanical resonator (e.g., on a bottom surface of the encasement), one or more openings positioned beside a portion of the mechanical resonator (e.g., on a side surface of the encasement, on a front surface of the encasement, on a back surface of the encasement, on a surface of the encasement proximal to the probe, on a surface of the encasement distal to the probe), one or more openings positioned at an end of the mechanical resonator (e.g., on a side surface of the encasement, on a front surface of the encasement, on a surface of the encasement proximal to the probe), and/or one or more openings positioned above a portion of the mechanical resonator (e.g., on a top surface of the encasement). In some embodiments, the encasement may include no openings positioned proximate the mechanical resonator, may include no openings proximate the mechanical resonator other than an opening through which a probe protrudes, or may include no openings positioned beneath the mechanical resonator.

In some embodiments, such as is shown in FIGS. 1A-1C, an encasement may comprise one or more openings positioned proximate to a portion of a probe. The encasement may comprise one or more openings positioned beneath a portion of the probe (e.g., through which the probe protrudes, on a bottom surface of the encasement), one or more openings positioned beside a portion of the probe (e.g., on a side surface of the encasement, on a front surface of the encasement, on a surface of the encasement proximal to the probe), and/or one or more openings positioned above a portion of the probe (e.g., on a top surface of the encasement). In some embodiments, the encasement may only include a single opening proximate the probe (e.g., the opening through which the probe protrudes). In other embodiments, the encasement may include multiple openings proximate the probe (e.g., the opening through which the probe protrudes and one or more other openings).

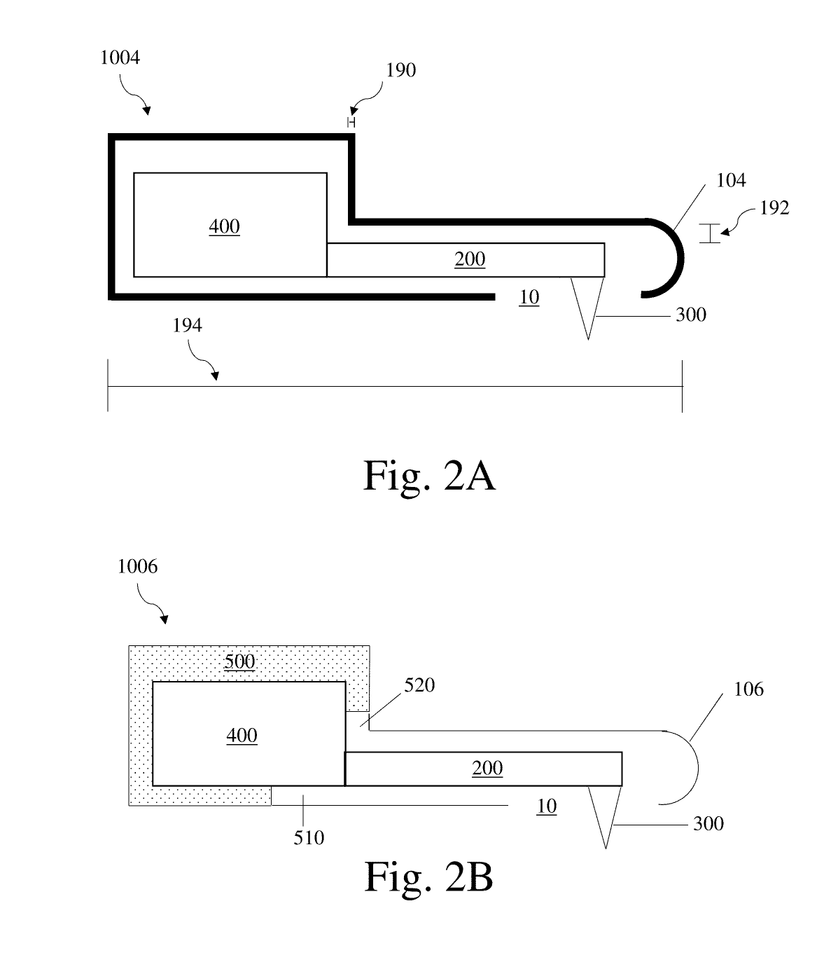

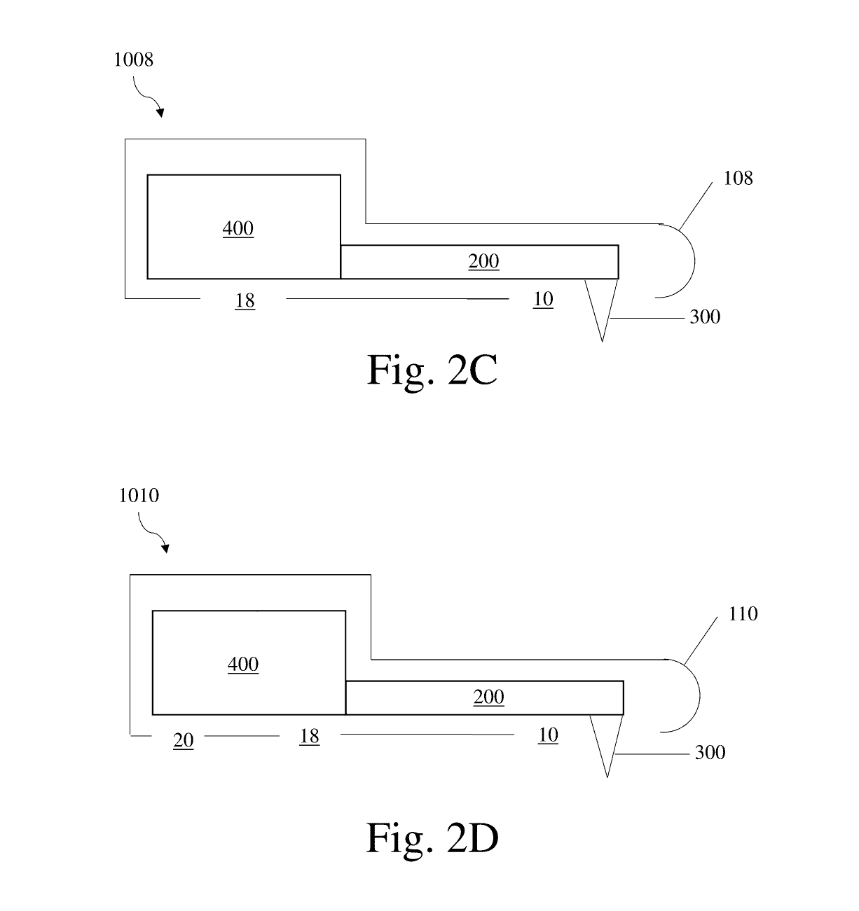

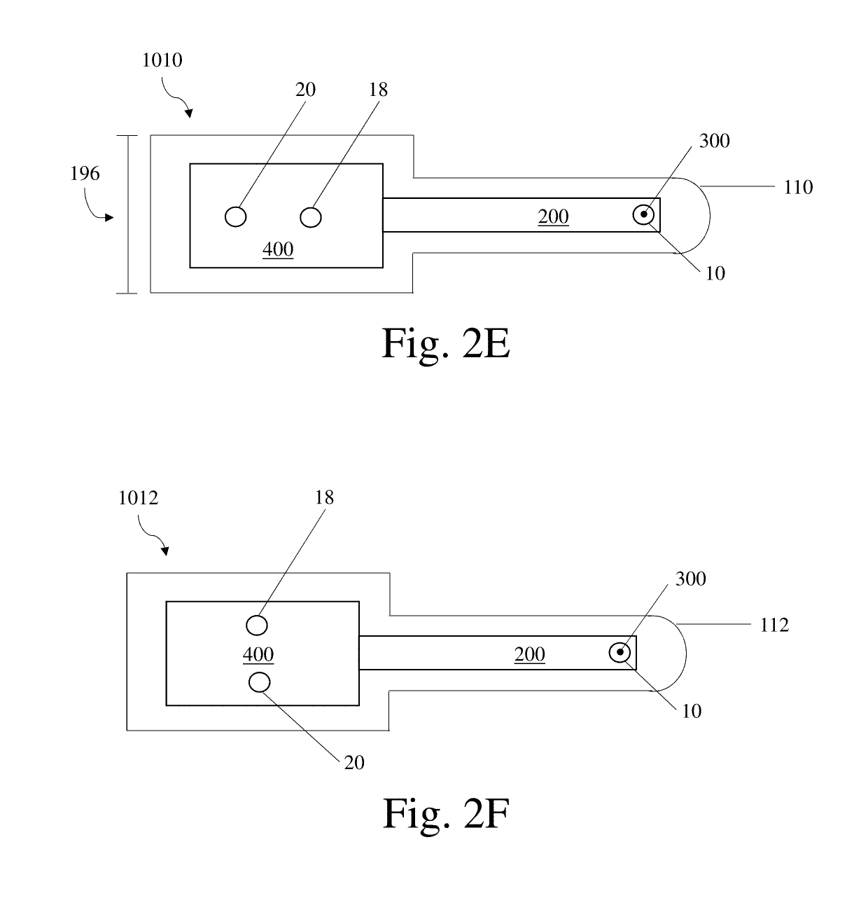

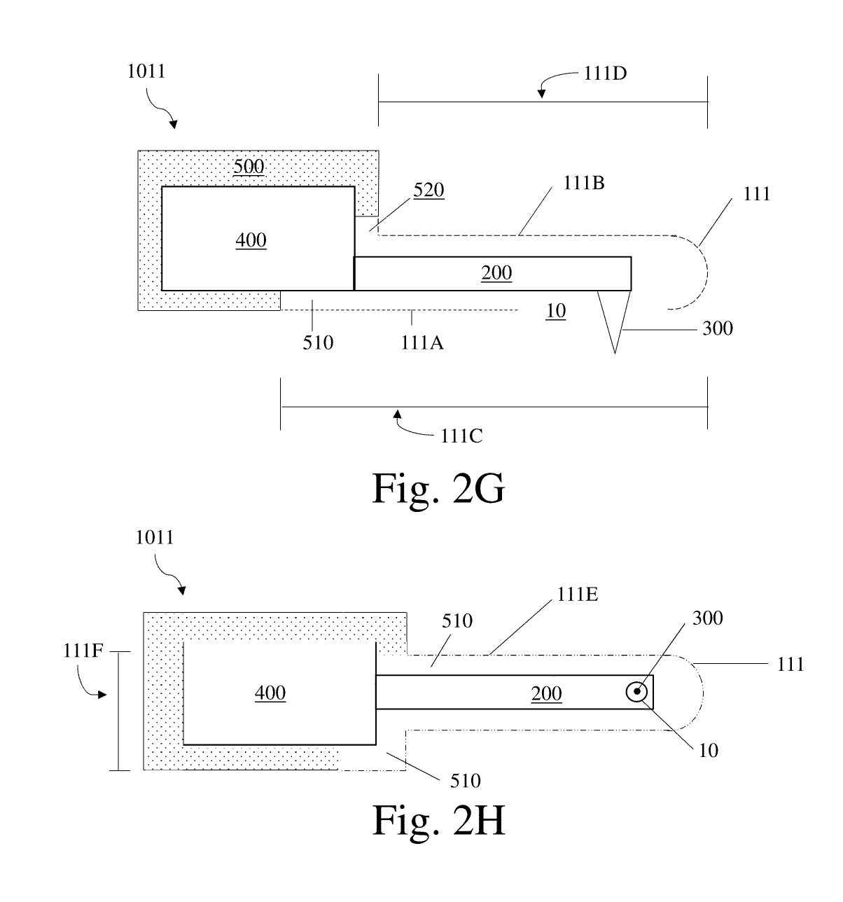

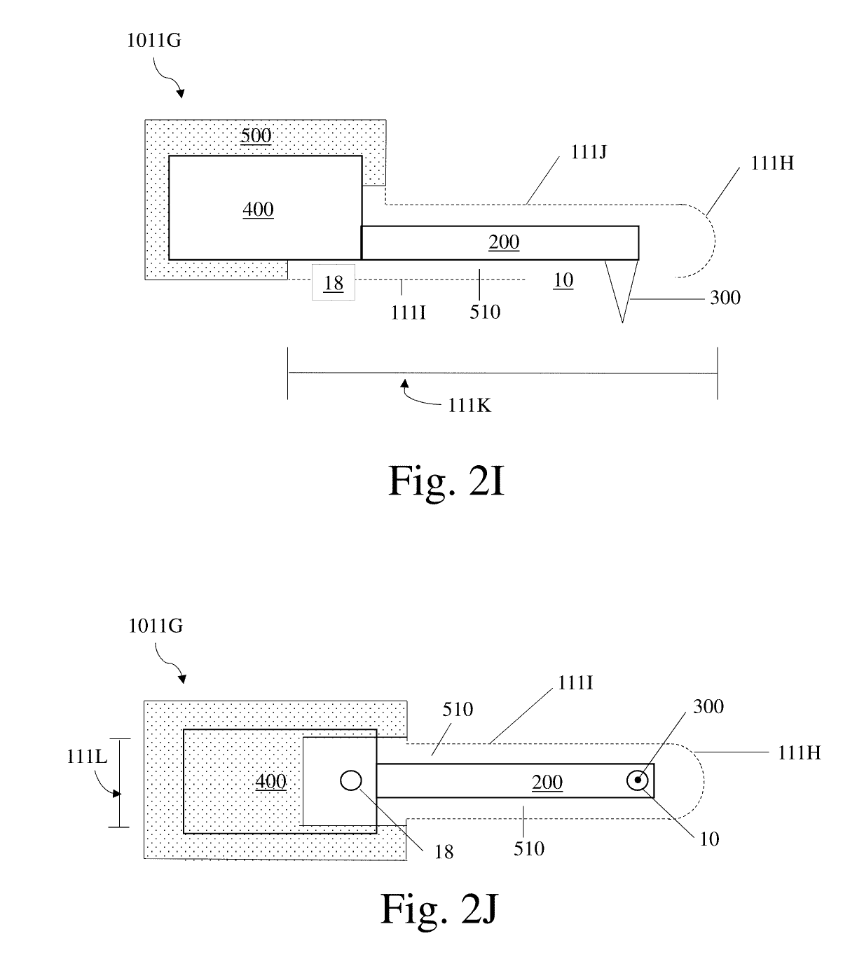

In some embodiments, a sensor may further comprise one or more components not shown in FIGS. 1A-1C. For example, in some embodiments, a sensor may further comprise a chip. The mechanical resonator may be attached to the chip, and/or manipulation of the mechanical resonator may be facilitated by the chip. FIG. 2A shows one non-limiting embodiment of a sensor 1004 comprising an encasement 104 comprising first opening 10, mechanical resonator 200, probe 300, and a chip 400. Encasement 104 has a thickness 190, is positioned a distance 192 from the mechanical resonator, and has a length 194. The mechanical resonator may be a cantilever (e.g., like the cantilever shown in FIG. 2A), in certain embodiments. For instance, the mechanical resonator may be a suspended beam attached to the chip. As shown illustratively in FIG. 2A, in certain embodiments, the encasement encases the chip.

In some embodiments, as will be described further below, one or more materials may be positioned between at least a portion of the chip and at least a portion of the encasement. These material(s) may at least partially encase the chip, in certain cases. For example, in FIG. 2B, sacrificial layer 500 is positioned between a portion of chip 400 and a portion of encasement 106. Encased volumes 510 and 520 are positioned between chip 400 and encasement 106, but do not include any portion of sacrificial layer 500.

In some embodiments, a sensor may comprise an encasement and a sacrificial layer positioned between at least a portion of the chip and at least a portion of the encasement, and the encasement may comprise one or more portions which do not encase a sacrificial layer, such as portions that encase encased volumes 510 and 520 in FIG. 2B. In other words, in some embodiments, a sensor comprises an encasement comprising one or more portions for which no portion of a sacrificial layer is positioned between the portion of the encasement and the portion of the mechanical resonator or chip closest to the portion of the encasement. Such portions of the encasement are referred to herein as encasement portions, i.e., portions of the encasement not encasing a sacrificial layer. For instance, in FIG. 2G, encasement portion 111A and encasement portion 111B are portions of encasement 111 not encasing a sacrificial layer. Encasement portion encasement 111A encases a portion of chip 400, mechanical resonator 200, and encased volume 510. Encasement portion 111B encases a portion of chip 400, mechanical resonator 200, and encased volume 520. FIG. 2H shows a bottom view of the encasement shown in FIG. 2G, in which encasement portion 111E encases a portion of chip 400, mechanical resonator 200, and encased volume 510.

When present, the sacrificial layer should be understood to be capable of having a different configuration than that shown in FIG. 2B in some embodiments. For instance, the sacrificial layer may be smaller or larger, may not be present or minimally present in one or more areas (e.g., between the bottom surface of the chip and the encasement), may fully encase the chip, etc. In some embodiments, the sacrificial layer does not extend onto the mechanical resonator, and/or is not directly adjacent to the mechanical resonator. It should be understood that a sacrificial layer positioned between a portion of the chip and a portion of the encasement may be present in any suitable embodiments, including those depicted in other figures herein in which it is not shown. In some embodiments, the encasement may comprise a second opening that is positioned proximate the chip. For example, in FIG. 2C, a sensor 1008 comprises an encasement 108 which comprises first opening 10 through which probe 300 protrudes and second opening 18 positioned proximate chip 400. In some embodiments, a subset of the openings positioned on the encasement (e.g., the opening through which the probe protrudes and a second opening positioned proximate the chip, two or more openings positioned on the encasement, each opening on the encasement) may be in fluid communication each other, such as in fluid communication with each other along a pathway that passes through the volume enclosed by the encasement and/or along a pathway that is encased by the encasement.

In some embodiments, such as that shown in FIG. 2C, an encasement may comprise an opening positioned proximate a chip that is positioned on the same surface of the encasement as the first opening through which the probe protrudes. In some embodiments, the encasement may comprise an opening positioned proximate a chip that is positioned on a different surface of the encasement from the first opening through which the probe protrudes. The encasement may comprise one or more openings positioned beneath a portion of the chip (e.g., on a bottom surface of the encasement), one or more openings positioned beside a portion of the chip (e.g., on a side surface of the encasement, on a back surface of the encasement, on a surface of the encasement distal to the probe), and/or one or more openings positioned above a portion of the chip (e.g., on a top surface of the encasement). In some embodiments, the encasement may include no openings positioned proximate the chip, may only include no openings proximate chip other than an opening through which a probe protrudes, or may include no openings positioned beneath the chip.

In certain cases, a sensor may comprise a chip and an encasement that comprises two or more openings positioned proximate the chip. FIGS. 2D and 2E show one example of a sensor 1010 comprising an encasement 110. In these figures, the encasement has width 196 and comprises openings 10, 18, and 20. Openings 18 and 20 are both positioned beneath the chip on the bottom surface of the encasement in FIGS. 2D-2E; opening 10, through which probe 300 protrudes, is also positioned on the bottom surface of the encasement. It should be noted that the arrangements of openings positioned proximate the chip shown in FIGS. 2D and 2E are merely exemplary and that other arrangements of openings positioned proximate the chip are also contemplated. For instance, FIG. 2F shows another possible configuration. When more than two openings are positioned proximate a chip, each opening may be positioned on the same surface of the encasement (as in FIGS. 2D-2F), each opening may be positioned on a different surface of the encasement, or certain openings may be positioned on the same surface of the encasement as some openings and on a different surface of the encasement from other openings. When two or more openings are positioned on the same surface of the encasement proximate the chip, they may be equidistant from the probe, positioned at different distances from the probe, equidistant from each other, positioned at different distances from each other, equidistant from the closest external edge of the encasement to the opening, and/or positioned at different distances from the closest external edge of the encasement. In some embodiments, a sensor comprises an encasement and a sensor, the encasement comprises two openings on the same surface (e.g., beneath the chip), and the distance between the two openings is less than or equal to the length of a mechanical resonator.

It should be understood that a sensor may have a design similar to that shown in any of the figures herein (e.g., in any of FIGS. 2C-2F), and may further comprise a sacrificial layer positioned between a portion of a chip and a portion of an encasement. For instance, a sensor may comprise an encasement comprising two or more openings, a chip, and a sacrificial layer positioned between a portion of a chip and a portion of the encasement. An example of a sensor comprising an encasement comprising two openings, a chip, and a sacrificial layer positioned between a portion of a chip and a portion of the encasement is shown in FIG. 2I. FIG. 2J shows a side view of FIG. 2I. In FIGS. 2I and 2J, encasement portion 111I and encasement portion 111J are portions of encasement 111H not encasing a sacrificial layer. Encasement portion encasement 111I encases a portion of chip 400, mechanical resonator 200, and encased volume 510. Encasement portion 111J encases a portion of chip 400, mechanical resonator 200, and encased volume 520.

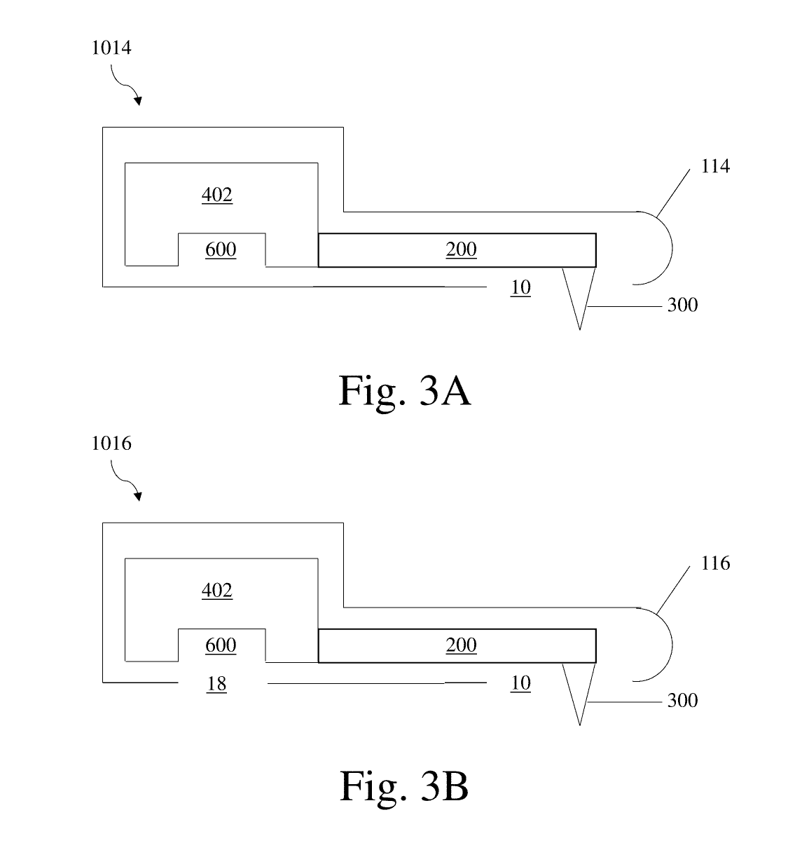

In some embodiments, a sensor may comprise a chip, and the chip may comprise a reservoir. The reservoir may increase the volume of a fluid (e.g., a first fluid such as a gas, such as air, nitrogen helium, and/or argon) that may be encased by the encasement. FIG. 3A shows one example of a sensor 1014 comprising a chip 402 including a reservoir 600. In some embodiments, the reservoir may be in fluid communication with an opening positioned on the encasement (e.g., an opening through which a probe protrudes, an opening positioned proximate the chip, an opening positioned proximate a mechanical resonator), such as in fluid communication along a pathway that passes through the volume enclosed by the encasement and/or along a pathway that is encased by the encasement. In some embodiments, such as FIG. 3B, a sensor may comprise a reservoir and comprise an encasement that includes an opening positioned proximate the reservoir. In FIG. 3B, a sensor 1016 comprises chip 402 with reservoir 600; sensor 1016 also comprises encasement 114 with opening 10 through which probe 300 protrudes and opening 18 positioned proximate (e.g., adjacent) reservoir 600.

It should be understood that certain sensors may comprise combinations of the features shown in FIGS. 1-3. For instance, certain sensors may comprise one or more openings positioned on the encasement proximate to a chip and one or more openings on the encasement proximate to a mechanical resonator. As another example, certain sensors may comprise one or more openings positioned on the encasement proximate to (e.g., adjacent) a reservoir and one or more openings positioned on the encasement proximate to (e.g., adjacent) a mechanical resonator.

It should also be understood that the features shown in FIGS. 1-3 are merely schematic, and that the components shown in FIGS. 1-3 may have different sizes, shapes, positions and/or other characteristics than those shown in FIGS. 1-3. Some of these variations are listed below.

For example, a sensor may comprise a chip having a design other than the designs shown in the Figures. The chip may have a design similar to one of the chip designs shown in U.S. Pat. No. 9,229,028, which is incorporated by reference herein in its entirety for all purposes. In other words, a sensor may comprise a chip having a design similar to one of the chip designs shown in U.S. Pat. No. 9,229,028, comprise an encasement including one or more openings as described herein, and/or comprise further components as described herein.

As another example, one or more features of a chip may be different than those shown in the Figures. For instance, a sensor may comprise a chip in which one or more angles are characteristic of angles formed by silicon etching (e.g., the chip may have a substantially trapezoidal cross section across its length and/or width).

As a third example, one or more features of an encasement may be different than those shown in the Figures. For instance, in some embodiments some portions of the sensor are not encased by the encasement (e.g., one or more portions of a chip are not encased by the encasement). In some embodiments, one or more positions of the sensor other than a sacrificial layer may be directly adjacent the encasement (e.g., one or more portions of a chip may be directly adjacent the encasement).

As a fourth example, in some embodiments one or more openings may vary from the openings shown in the Figures in one or more ways. For instance, one or more openings may have shapes other than circular. One or more openings may be asymmetric, oval, and/or diamond-shaped in certain cases.

As a fifth example, in some embodiments there may be one or more differences between the probe and the probes shown in the Figures. For instance, the probe may be asymmetric.

As described above, in certain embodiments, a sensor may comprise an encasement comprising an opening through which a probe protrudes. When present, the opening through which the probe protrudes may have any suitable size and shape. In some embodiments, the opening through which the probe protrudes has a largest cross-sectional dimension of greater than or equal to 100 nm, greater than or equal to 200 nm, greater than or equal to 500 nm, greater than or equal to 1 micron, greater than or equal to 2 microns, greater than or equal to 5 microns, greater than or equal to 10 microns, greater than or equal to 20 microns, greater than or equal to 50 microns, or greater than or equal to 100 microns. In some embodiments, the opening through which the probe protrudes has a largest cross-sectional dimension of less than or equal to 200 microns, less than or equal to 100 microns, less than or equal to 50 microns, less than or equal to 20 microns, less than or equal to 10 microns, less than or equal to 5 microns, less than or equal to 2 microns, less than or equal to 1 micron, less than or equal to 500 nm, or less than or equal to 200 nm. Combinations of the above-referenced ranges are also possible (e.g., greater than or equal to 100 nm and less than or equal to 200 microns, or greater than or equal to 2 microns and less than or equal to 200 microns). Other ranges are also possible. As used herein, the largest cross-sectional dimension of the opening through which the probe protrudes is the longest straight line that may be drawn from one point on the encasement across the opening through which the probe protrudes to another point on the encasement and only intersects the encasement at its endpoints.

When present, an opening through which a probe protrudes may have any suitable area. The area of the opening through which the probe protrudes may be greater than or equal to 0.01 micron², greater than or equal to 0.02 microns², greater than or equal to 0.05 microns², greater than or equal to 0.1 micron², greater than or equal to 0.2 microns², greater than or equal to 0.5 microns², greater than or equal to 1 micron², greater than or equal to 2 microns², greater than or equal to 5 microns², greater than or equal to 10 microns², greater than or equal to 2*10¹ microns², greater than or equal to 5*10¹ microns², greater than or equal to 10² microns², greater than or equal to 2*10² microns², greater than or equal to 5*10² microns², greater than or equal to 10³ microns², greater than or equal to 2*10³ microns², greater than or equal to 5*10³ microns², or greater than or equal to 10⁴ microns². The area of the opening through which the probe protrudes may be less than or equal to 5*10⁴ microns², less than or equal to 2*10⁴ microns², less than or equal to 10⁴ microns², less than or equal to 5*10³ microns², less than or equal to 2*10³ microns², less than or equal to 10³ microns², less than or equal to 5*10² microns², less than or equal to 2*10² microns², less than or equal to 10² microns², less than or equal to 5*10² microns², less than or equal to 2*10¹ microns², less than or equal to 10 microns², less than or equal to 5 microns², less than or equal to 2 microns², less than or equal to 1 micron², less than or equal to 0.5 microns², less than or equal to 0.2 microns², less than or equal to 0.1 micron², or less than or equal to 0.05 microns². Combinations of the above-referenced ranges are also possible (e.g., greater than or equal to 0.01 micron² and less than or equal to 5*10⁴ microns², greater than or equal to 2 microns² and less than or equal to 5*10⁴ microns², or greater than or equal to 10² microns² and less than or equal to 5*10⁴ microns²). Other ranges are also possible.

As described above, in certain embodiments a sensor comprises an encasement comprising one or more openings proximate (e.g., adjacent to) a mechanical resonator (e.g., a mechanical resonator encased by the encasement). When an encasement comprises two or more openings proximate the mechanical resonator, each opening proximate the mechanical resonator may have the same largest cross-sectional dimension, or two or more openings proximate the mechanical resonator may have different largest cross-sectional dimensions. When an encasement comprises two or more openings proximate the mechanical resonator, each opening proximate the mechanical resonator may have substantially the same area, or two or more openings proximate the mechanical resonator may have different areas.

In some embodiments, an encasement may comprise one or more openings proximate the mechanical resonator and an opening through which a probe protrudes, and one or more of the opening(s) proximate the mechanical resonator may each have a largest cross-sectional dimension that is smaller than the largest cross-sectional dimension of the opening through which the probe protrudes. In some embodiments, an encasement may comprise one or more openings proximate the mechanical resonator and an opening through which a probe protrudes, and each of the opening(s) proximate the mechanical resonator may have a largest cross-sectional dimension that is smaller than the largest cross-sectional dimension of the opening through which the probe protrudes.

In some embodiments, an encasement may comprise one or more openings proximate (e.g., adjacent to) a mechanical resonator, and each opening proximate the mechanical resonator may independently have a largest cross-sectional dimension that falls into one or more of the ranges listed below. In some embodiments, an encasement may comprise one or more openings proximate a mechanical resonator with a largest cross-sectional dimension of greater than or equal to 100 nm, greater than or equal to 200 nm, greater than or equal to 500 nm, greater than or equal to 1 micron, greater than or equal to 2 microns, greater than or equal to 5 microns, greater than or equal to 10 microns, greater than or equal to 20 microns, greater than or equal to 50 microns, or greater than or equal to 100 microns. In some embodiments, an encasement may comprise one or more openings proximate a mechanical resonator with a largest cross-sectional dimension of less than or equal to 200 microns, less than or equal to 100 microns, less than or equal to 50 microns, less than or equal to 20 microns, less than or equal to 10 microns, less than or equal to 5 microns, less than or equal to 2 microns, less than or equal to 1 micron, less than or equal to 500 nm, or less than or equal to 200 nm. Combinations of the above-referenced ranges are also possible (e.g., greater than or equal to 100 nm and less than or equal to 200 microns, greater than or equal to 100 nm and less than or equal to 100 microns, or greater than or equal to 1 micron and less than or equal to 10 microns). Other ranges are also possible (e.g., each opening proximate the mechanical resonator may independently have a largest cross-sectional dimension that falls outside of one or more of the ranges listed above). As used herein, the largest cross-sectional dimension of an opening proximate a mechanical resonator is the longest straight line that may be drawn from one point on the encasement across the opening through which the probe protrudes to another point on the encasement that only intersects the encasement at its endpoints.

In some embodiments, an encasement may comprise one or more openings proximate the mechanical resonator and an opening through which a probe protrudes, and one or more of the opening(s) (e.g., each of the opening(s)) proximate the mechanical resonator may each have an area that is smaller than the area of the opening through which the probe protrudes.

In some embodiments, an encasement may comprise one or more openings proximate a mechanical resonator, and each opening proximate the mechanical resonator may independently have an area that falls into one or more of the ranges listed below. In some embodiments, an encasement may comprise one or more openings proximate a mechanical resonator with an area of greater than or equal to 10⁻² microns², greater than or equal to 2*10⁻² microns², greater than or equal to 5*10⁻² microns², greater than or equal to 10⁻¹ microns², greater than or equal to 2*10⁻¹ microns², greater than or equal to 5*10⁻¹ microns², greater than or equal to 1 micron², greater than or equal to 2 microns², greater than or equal to 5 microns², greater than or equal to 10 microns², greater than or equal to 2*10¹ microns², greater than or equal to 5*10¹ microns², greater than or equal to 10² microns², greater than or equal to 2*10² microns², greater than or equal to 5*10² microns², greater than or equal to 10³ microns², greater than or equal to 2*10³ microns², greater than or equal to 5*10³ microns², or greater than or equal to 1*10⁴ microns². In some embodiments, an encasement may comprise one or more openings proximate a mechanical resonator with an area of less than or equal to 5*10⁴ microns², less than or equal to 2*10⁴ microns², less than or equal to 10⁴ microns², less than or equal to 5*10³ microns², less than or equal to 2*10³ microns², less than or equal to 10³ microns², less than or equal to 5*10² microns², less than or equal to 2*10² microns², less than or equal to 10² microns², less than or equal to 5*10¹ microns², less than or equal to 2*10¹ microns², less than or equal to 10 microns², less than or equal to 5 microns², less than or equal to 2 microns², less than or equal to 1 micron², less than or equal to 5*10⁻¹ microns², less than or equal to 2*10⁻¹ microns², less than or equal to 10⁻¹ microns², or less than or equal to 5*10⁻² microns². Combinations of the above-referenced ranges are also possible (e.g., greater than or equal to 10⁻² microns² and less than or equal to 5*10⁴ microns², or greater than or equal to 1 micron² and less than or equal to 10² microns²). Other ranges are also possible (e.g., each opening proximate the mechanical resonator may independently have an area that falls outside of one or more of the ranges listed above).

As described above, in certain embodiments a sensor may comprise an encasement encasing a chip, and the encasement may comprise one or more openings proximate (e.g., adjacent to) the chip. When an encasement comprises two or more openings proximate the chip, each opening proximate the chip may have the same largest cross-sectional dimension, or two or more openings proximate the chip may have different largest cross-sectional dimensions. When an encasement comprises two or more openings proximate the chip, each opening proximate the chip may have substantially the same area, or two or more openings proximate the chip may have different areas.

In some embodiments, an encasement may comprise one or more openings proximate (e.g., adjacent to) a chip and an opening through which a probe protrudes, and one or more of the opening(s) (e.g., each of the opening(s) proximate the chip) may each have a largest cross-sectional dimension that is equivalent in size to, or larger than, the largest cross-sectional dimension of the opening through which the probe protrudes. In some embodiments, an encasement may comprise one or more openings proximate (e.g., adjacent to) a chip and an opening through which a probe protrudes, and each opening proximate the chip may independently have a largest cross-sectional dimension that falls into one or more of the ranges listed below. In some embodiments, an encasement may comprise one or more openings proximate a chip with a largest cross-sectional dimension that is 0% larger than the largest cross-sectional dimension of the opening through which the probe protrudes, greater than or equal to 10% larger than the largest cross-sectional dimension of the opening through which the probe protrudes, greater than or equal to 20% larger than the largest cross-sectional dimension of the opening through which the probe protrudes, greater than or equal to 50% larger than the largest cross-sectional dimension of the opening through which the probe protrudes, greater than or equal to 100% larger than the largest cross-sectional dimension of the opening through which the probe protrudes, greater than or equal to 125% larger than the largest cross-sectional dimension of the opening through which the probe protrudes, greater than or equal to 200% larger than the largest cross-sectional dimension of the opening through which the probe protrudes, or greater than or equal to 500% larger than the largest cross-sectional dimension of the opening through which the probe protrudes. In some embodiments, an encasement may comprise one or more openings proximate a chip with a largest cross-sectional dimension that is less than or equal to 1,000% larger than the largest cross-sectional dimension of the opening through which the probe protrudes, less than or equal to 500% larger than the largest cross-sectional dimension of the opening through which the probe protrudes, less than or equal to 200% larger than the largest cross-sectional dimension of the opening through which the probe protrudes, less than or equal to 125% larger than the largest cross-sectional dimension of the opening through which the probe protrudes, less than or equal to 100% larger than the largest cross-sectional dimension of the opening through which the probe protrudes, less than or equal to 50% larger than the largest cross-sectional dimension of the opening through which the probe protrudes, less than or equal to 20% larger than the largest cross-sectional dimension of the opening through which the probe protrudes, or less than or equal to 10% larger than the largest cross-sectional dimension of the opening through which the probe protrudes. Combinations of the above-referenced ranges are also possible (e.g., greater than or equal to 0% larger and less than or equal to 1,000% larger, or greater than or equal to 125% larger and less than or equal to 1,000% larger). Other ranges are also possible (e.g., each opening proximate the chip may independently have a largest cross-sectional dimension that falls outside of one or more of the ranges listed above). As used herein, the largest cross-sectional dimension of an opening (e.g., an opening through which a probe protrudes, an opening proximate a chip) is the longest straight line that may be drawn from one point on the encasement across the opening through which the probe protrudes to another point on the encasement that only intersects the encasement at its endpoints.

In some embodiments, an encasement may comprise one or more openings proximate (e.g., adjacent to) a chip, and each opening proximate the chip may independently have a largest cross-sectional dimension that falls into one or more of the ranges listed below. In some embodiments, an encasement may comprise one or more openings proximate a chip with a largest cross-sectional dimension of greater than or equal to 100 nm, greater than or equal to 200 nm, greater than or equal to 500 nm, greater than or equal to 1 micron, greater than or equal to 2 microns, greater than or equal to 5 microns, greater than or equal to 10 microns, greater than or equal to 20 microns, greater than or equal to 50 microns, greater than or equal to 100 microns, greater than or equal to 200 microns, or greater than or equal to 500 microns. In some embodiments, an encasement may comprise one or more openings proximate a chip with a largest cross-sectional dimension of less than or equal to 1 mm, less than or equal to 500 microns, less than or equal to 200 microns, less than or equal to 100 microns, less than or equal to 50 microns, less than or equal to 20 microns, less than or equal to 10 microns, less than or equal to 5 microns, less than or equal to 2 microns, less than or equal to 1 micron, less than or equal to 500 nm, or less than or equal to 200 nm. Combinations of the above-referenced ranges are also possible (e.g., greater than or equal to 100 nm and less than or equal to 1 mm, or greater than or equal to 20 microns and less than or equal to 50 microns). Other ranges are also possible (e.g., each opening proximate the chip may independently have a largest cross-sectional dimension that falls outside of one or more of the ranges listed above). As used herein, the largest cross-sectional dimension of an opening proximate a chip is the longest straight line that may be drawn from one point on the encasement across the opening through which the probe protrudes to another point on the encasement that only intersects the encasement at its endpoints.

In some embodiments, an encasement may comprise one or more openings proximate (e.g., adjacent to) a chip and an opening through which a probe protrudes, and one or more of the opening(s) proximate the chip (e.g., each of the opening(s) proximate the chip) may each have an area that is equivalent in size to or larger than the area of the opening through which the probe protrudes. In some embodiments, an encasement may comprise one or more openings proximate (e.g., adjacent to) a chip and an opening through which a probe protrudes, and each opening proximate the chip may independently have an area that falls into one or more of the ranges listed below. In some embodiments, an encasement may comprise one or more openings proximate a chip with an area that is greater than or equal to 0% larger than the area of the opening through which the probe protrudes, greater than or equal to 20% larger than the area of the opening through which the probe protrudes, greater than or equal to 50% larger than the area of the opening through which the probe protrudes, greater than or equal to 100% larger than the area of the opening through which the probe protrudes, greater than or equal to 110% larger than the area of the opening through which the probe protrudes, greater than or equal to 200% larger than the area of the opening through which the probe protrudes, greater than or equal to 500% larger than the area of the opening through which the probe protrudes, greater than or equal to 1,000% larger than the area of the opening through which the probe protrudes, greater than or equal to 2,000% larger than the area of the opening through which the probe protrudes, or greater than or equal to 5,000% larger than the area of the opening through which the probe protrudes. In some embodiments, an encasement may comprise one or more openings proximate a chip with an area that is less than or equal to 10,000% larger than the area of an opening through which the probe protrudes, less than or equal to 5,000% larger than the area of an opening through which the probe protrudes, less than or equal to 2,000% larger than the area of an opening through which the probe protrudes, less than or equal to 1,000% larger than the area of an opening through which the probe protrudes, less than or equal to 500% larger than the area of an opening through which the probe protrudes, less than or equal to 200% larger than the area of an opening through which the probe protrudes, less than or equal to 110% larger than the area of an opening through which the probe protrudes, less than or equal to 100% larger than the area of an opening through which the probe protrudes, less than or equal to 50% larger than the area of an opening through which the probe protrudes, or less than or equal to 20% larger than the area of an opening through which the probe protrudes. Combinations of the above-referenced ranges are also possible (e.g., greater than or equal to 0% larger and less than or equal to 10,000% larger, or greater than or equal to 110% larger and less than or equal to 10,000% larger). Other ranges are also possible (e.g., each opening proximate the chip may independently have a largest cross-sectional dimension that falls outside of one or more of the ranges listed above).

In some embodiments, an encasement may comprise one or more openings proximate (e.g., adjacent to) a chip, and each opening proximate the chip may independently have an area that falls into one or more of the ranges listed below. In some embodiments, an encasement may comprise one or more openings proximate a chip with an area of greater than or equal to 8*10⁻³ microns², greater than or equal to 10⁻² microns², greater than or equal to 2*10⁻² microns², greater than or equal to 5*10⁻² microns², greater than or equal to 10⁻¹ microns², greater than or equal to 2*10⁻¹ microns², greater than or equal to 5*10⁻¹ microns², greater than or equal to 1 microns², greater than or equal to 2 microns², greater than or equal to 5 microns², greater than or equal to 10 microns², greater than or equal to 2*10¹ microns², greater than or equal to 5*10¹ microns², greater than or equal to 10² microns², greater than or equal to 2*10² microns², greater than or equal to 5*10² microns², greater than or equal to 10³ microns², greater than or equal to 2*10³ microns², greater than or equal to 5*10³ microns², greater than or equal to 10⁴ microns², greater than or equal to 2*10⁴ microns², greater than or equal to 5*10⁴ microns², greater than or equal to 10⁵ microns², greater than or equal to 2*10⁵ microns², greater than or equal to 5*10⁵ microns², greater than or equal to 10⁶ microns², greater than or equal to 2*10⁶ microns², greater than or equal to 5*10⁶ microns², greater than or equal to 10⁷ microns², greater than or equal to 2*10⁷ microns², or greater than or equal to 5*10⁷ microns². In some embodiments, an encasement may comprise one or more openings proximate a chip with an area of less than or equal to 8*10⁷ microns², less than or equal to 5*10⁷ microns², less than or equal to 2*10⁷ microns², less than or equal to 10⁷ microns², less than or equal to 5*10⁶ microns², less than or equal to 2*10⁶ microns², less than or equal to 10⁶ microns², less than or equal to 5*10⁵ microns², less than or equal to 2*10⁵ microns², less than or equal to 10⁵ microns², less than or equal to 5*10⁴ microns², less than or equal to 2*10⁴ microns², less than or equal to 10⁴ microns², less than or equal to 5*10³ microns², less than or equal to 2*10³ microns², less than or equal to 10³ microns², less than or equal to 5*10² microns², less than or equal to 2*10² microns², less than or equal to 10² microns², less than or equal to 5*10¹ microns², less than or equal to 2*10¹ microns², less than or equal to 10 microns², less than or equal to 5 microns², less than or equal to 2 microns², less than or equal to 1 micron², less than or equal to 5*10⁻¹ microns², less than or equal to 2*10⁻¹ microns², less than or equal to 10⁻¹ microns², less than or equal to 5*10⁻² microns², less than or equal to 2*10⁻² microns², or less than or equal to 10⁻² microns². Combinations of the above-referenced ranges are also possible (e.g., greater than or equal to 8*10⁻³ microns² and less than or equal to 8*10⁷ microns²). Other ranges are also possible (e.g., each opening proximate the chip may independently have a largest cross-sectional dimension that falls outside of one or more of the ranges listed above).

As described above, certain embodiments relate to sensors that comprise encasements. In some embodiments, the encasement may have one or more features (other than any openings thereon) that improve one or more properties of the sensor. For instance, in some embodiments, the encasement may encase a fluid in addition to one or more other components. The fluid may be a fluid that it is desirable for the mechanical resonator to resonate in (e.g., a first fluid such as a gas, such as air, nitrogen, helium, and/or argon). The encasement may encase the fluid in one or more of the following non-limiting situations: prior to employing the sensor in an imaging process, while employing the sensor in an imaging process, after employing the sensor in an imaging process, prior to exposing the encasement to a different fluid (e.g., a liquid or a gas of different type than the first fluid), while exposing the encasement to a different fluid (e.g., a liquid), after exposing the encasement to a different fluid (e.g., a liquid or a gas of different type than the first fluid), prior to submerging the encasement in a different fluid (e.g., a liquid or a gas of different type than the first fluid), while submerging the encasement in a different fluid (e.g., a liquid or a gas of different type than the first fluid), after submerging the encasement in a different fluid (e.g., a liquid or a gas of different type than the first fluid). In certain cases, the encasement may encase the fluid in a situation other than those listed above.

In some embodiments, a fluid (e.g., a first fluid such as a gas, such as air, nitrogen, helium, and/or argon) may be positioned between a portion of the encasement and a portion of a mechanical resonator encased by the encasement. The encasement may encase a volume positioned between the encasement and the mechanical resonator (e.g., a volume at least partially occupied by the fluid) of greater than or equal to 10 pL, greater than or equal to 20 pL, greater than or equal to 50 pL, greater than or equal to 100 pL, greater than or equal to 200 pL, greater than or equal to 500 pL, greater than or equal to 1 nL, greater than or equal to 2 nL, greater than or equal to 5 nL, greater than or equal to 10 nL, greater than or equal to 20 nL, greater than or equal to 50 nL, greater than or equal to 100 nL, greater than or equal to 200 nL, greater than or equal to 500 nL, greater than or equal to 1 microliter, greater than or equal to 2 microliters, or greater than or equal to 5 microliters. The encasement may encase a volume positioned between the encasement and the mechanical resonator (e.g., a volume at least partially occupied by the fluid) of less than or equal to 10 microliters, less than or equal to 5 microliters, less than or equal to 2 microliters, less than or equal to 1 microliter, less than or equal to 500 nL, less than or equal to 200 nL, less than or equal to 100 nL, less than or equal to 50 nL, less than or equal to 20 nL, less than or equal to 10 nL, less than or equal to 5 nL, less than or equal to 2 nL, less than or equal to 1 nL, less than or equal to 500 pL, less than or equal to 200 pL, less than or equal to 100 pL, less than or equal to 50 pL, or less than or equal to 20 pL. Combinations of the above-referenced ranges are also possible (e.g., greater than or equal to 10 pL and less than or equal to 10 microliters, greater than or equal to 20 pL and less than or equal to 1 microliter, or greater than or equal to 200 pL and less than or equal to 1 microliter). Other ranges are also possible. The volume encased by the encasement and positioned between the encasement and the mechanical resonator can be determined by using a microscope to measure the internal dimensions of the portion of the encasement encasing the mechanical resonator and the external dimensions of the mechanical resonator, computing the volume encased by the portion of the encasement encasing the mechanical resonator and the volume of the mechanical resonator, and then subtracting the volume of the mechanical resonator from the volume encased by the portion of the encasement encasing the mechanical resonator.

In some embodiments, a fluid (e.g., a first fluid such as a gas, such as air, nitrogen, helium, and/or argon) may be positioned between a portion of the encasement and a portion of a chip encased by the encasement. The encasement may encase a volume positioned between the encasement and the chip (e.g., a volume at least partially occupied by the fluid) of greater than or equal to 10 pL, greater than or equal to 20 pL, greater than or equal to 50 pL, greater than or equal to 100 pL, greater than or equal to 200 pL, greater than or equal to 500 pL, greater than or equal to 1 nL, greater than or equal to 2 nL, greater than or equal to 5 nL, greater than or equal to 10 nL, greater than or equal to 20 nL, greater than or equal to 50 nL, greater than or equal to 100 nL, greater than or equal to 200 nL, greater than or equal to 500 nL, greater than or equal to 1 microliter, greater than or equal to 2 microliters, or greater than or equal to 5 microliters. The encasement may encase a volume positioned between the encasement and the mechanical resonator (e.g., a volume at least partially occupied by the fluid) of less than or equal to 10 microliters, less than or equal to 5 microliters, less than or equal to 2 microliters, less than or equal to 1 microliter, less than or equal to 500 nL, less than or equal to 200 nL, less than or equal to 100 nL, less than or equal to 50 nL, less than or equal to 20 nL, less than or equal to 10 nL, less than or equal to 5 nL, less than or equal to 2 nL, less than or equal to 1 nL, less than or equal to 500 pL, less than or equal to 200 pL, less than or equal to 100 pL, less than or equal to 50 pL, or less than or equal to 20 pL. Combinations of the above-referenced ranges are also possible (e.g., greater than or equal to 10 pL and less than or equal to 10 microliters, or greater than or equal to 10 pL and less than or equal to 10 nL). Other ranges are also possible. The volume encased by the encasement and positioned between the encasement and the chip can be determined by using a microscope to measure the internal dimensions of the encasement, the external dimensions of the chip, and the dimensions of a sacrificial layer positioned between the encasement and the chip (if present). Then, the volume encased by encasement, the volume of the chip, and the volume of the sacrificial layer (if any) may be computed. Finally, the volumes of the chip and sacrificial layer (if present) may be subtracted from the volume of the encasement. By way of example, this volume corresponds to the sum of encased volumes 510 and 520 shown in FIG. 2B.

In some embodiments, a sensor may comprise a chip comprising a reservoir, and the reservoir may comprise a fluid (e.g., a first fluid such as a gas, such as air, nitrogen, helium, and/or argon). In other words, in certain embodiments the encasement may encase a fluid that is positioned within a reservoir in a chip. The encasement may encase a volume positioned within the reservoir (e.g., a volume at least partially occupied by the fluid) of greater than or equal to 1 pL, greater than or equal to 2 pL, greater than or equal to 5 pL, greater than or equal to 10 pL, greater than or equal to 20 pL, greater than or equal to 50 pL, greater than or equal to 100 pL, greater than or equal to 200 pL, greater than or equal to 500 pL, greater than or equal to 1 nL, greater than or equal to 2 nL, greater than or equal to 5 nL, greater than or equal to 10 nL, greater than or equal to 20 nL, greater than or equal to 50 nL, greater than or equal to 100 nL, greater than or equal to 200 nL, greater than or equal to 500 nL, greater than or equal to 1 microliter, greater than or equal to 2 microliters, or greater than or equal to 5 microliters. The encasement may encase a volume positioned within the reservoir (e.g., a volume at least partially occupied by the fluid) of less than or equal to 6 microliters, less than or equal to 5 microliters, less than or equal to 2 microliters, less than or equal to 1 microliter, less than or equal to 500 nL, less than or equal to 200 nL, less than or equal to 100 nL, less than or equal to 50 nL, less than or equal to 20 nL, less than or equal to 10 nL, less than or equal to 5 nL, less than or equal to 2 nL, less than or equal to 1 nL, less than or equal to 500 pL, less than or equal to 200 pL, less than or equal to 100 pL, less than or equal to 50 pL, less than or equal to 20 pL, less than or equal to 10 pL, less than or equal to 5 pl, or less than or equal to 2 pL. Combinations of the above-referenced ranges are also possible (e.g., greater than or equal to 1 pL and less than or equal to 6 microliters). Other ranges are also possible. The volume encased by the encasement and positioned within the reservoir can be determined by using a microscope to measure the dimensions of the reservoir and then computing the volume of the reservoir.

In some embodiments, an encasement may encase a reservoir and a fluid, and the fluid that is positioned within the reservoir may make up a relatively high percentage of the total fluid encased by the encasement. The fluid positioned within the reservoir may make up greater than or equal to 1%, greater than or equal to 2%, greater than or equal to 5%, greater than or equal to 10%, greater than or equal to 25%, greater than or equal to 40%, greater than or equal to 50%, greater than or equal to 60%, greater than or equal to 75%, greater than or equal to 90%, greater than or equal to 95%, greater than or equal to 97%, or greater than or equal to 99% of the total fluid encased by the encasement. The fluid positioned within the reservoir may make up less than or equal to 100%, less than or equal to 99%, less than or equal to 97%, less than or equal to 95%, less than or equal to 90%, less than or equal to 75%, less than or equal to 60%, less than or equal to 50%, less than or equal to 40%, less than or equal to 25%, less than or equal to 10%, less than or equal to 5%, or less than or equal to 2% of the total fluid encased by the encasement. Combinations of the above-referenced ranges are also possible (e.g., greater than or equal to 1% and less than or equal to 100%). Other ranges are also possible.

In some embodiments, the total volume encased by the encasement that could be occupied by fluid (e.g., a first fluid such as a gas, such as air, nitrogen, helium, and/or argon) is the sum of the volumes discussed above. This volume may be greater than or equal to 1 pL, greater than or equal to 2 pL, greater than or equal to 5 pL, greater than or equal to 10 pL, greater than or equal to 20 pL, greater than or equal to 50 pL, greater than or equal to 100 pL, greater than or equal to 200 pL, greater than or equal to 500 pL, greater than or equal to 1 nL, greater than or equal to 5 nL, greater than or equal to 10 nL, greater than or equal to 20 nL, greater than or equal to 50 nL, greater than or equal to 100 nL, greater than or equal to 200 nL, greater than or equal to 500 nL, greater than or equal to 1 microliter, greater than or equal to 2 microliters, greater than or equal to 6 microliters, or greater than or equal to 7 microliters. In some embodiments, the total volume of the encasement that could be occupied by fluid (e.g., a first fluid such as a gas, such as air, nitrogen, helium, and/or argon) is less than or equal to 10 microliters, less than or equal to 7 microliters, less than or equal to 6 microliters, less than or equal to 2 microliters, less than or equal to 1 microliter, less than or equal to 500 nL, less than or equal to 200 nL, less than or equal to 100 nL, less than or equal to 50 nL, less than or equal to 20 nL, less than or equal to 10 nL, less than or equal to 5 nL, less than or equal to 2 nL, less than or equal to 1 nL, less than or equal to 500 pL, less than or equal to 200 pL, less than or equal to 100 pL, less than or equal to 50 pL, less than or equal to 20 pL, less than or equal to 10 pL, less than or equal to 5 pL, or less than or equal to 2 pL. Combinations of the above-referenced ranges are also possible (e.g., greater than or equal to 1 pL and less than or equal to 6 microliters, greater than or equal to 10 pL and less than or equal to 10 microliters, or greater than or equal to 20 pL and less than or equal to 7 microliters). Other ranges are also possible. The total volume of the encasement that could be occupied by fluid can be determined by using a microscope to measure the internal dimensions of the encasement and the solid components encased therein, computing the volume encased by encasement and the volume of the solid components therein, and then subtracting the volume of the encased solid components from the volume of the encasement.

In some embodiments, the encasement may have one or more features that reduce the intrusion of liquid into the encasement, and/or one or more features that reduce the condensation of one or more species on a surface (e.g., an interior surface) of the encasement. For example, in some embodiments, the encasement may be hydrophobic and/or comprises one or more surfaces that are hydrophobic (e.g., one, more than one, or all interior surface(s) of the encasement). In some embodiments, one or more surfaces of the encasement (e.g., one, more, or all interior surface(s) of the encasement) may have a relatively high contact angle. One or more surfaces of the encasement may have a water contact angle of greater than or equal to 40°, greater than or equal to 60°, greater than or equal to 80°, greater than or equal to 100°, greater than or equal to 120°, greater than or equal to 140°, or greater than or equal to 160°. One or more surfaces of the encasement may have a water contact angle of less than or equal to 180°, less than or equal to 160°, less than or equal to 140°, less than or equal to 120°, less than or equal to 100°, less than or equal to 80°, or less than or equal to 60°. Combinations of the above-referenced ranges are also possible (e.g., greater than or equal to 40° and less than or equal to 180°, greater than or equal to 40° and less than or equal to 120°, greater than or equal to 80° and less than or equal to 180°, or greater than or equal to 80° and less than or equal to 120°). Other ranges are also possible. The water contact angle may be determined by formulating a surface identical in chemistry and surface roughness to the relevant surface of the encasement, adding a water droplet with a 1 mm diameter to the surface, and measuring the contact angle with a contact angle goniometer.

In certain cases, an encasement may comprise a hydrophobic coating (e.g., on one, more, or all interior surface(s) of the encasement). When present, the hydrophobic coating may include a polymer (e.g., an organic polymer, a fluorinated polymer, a fluorinated organic polymer) and/or a monolayer (e.g., a self-assembled monolayer). Certain appropriate polymers may be formed by a chemical vapor deposition process, such as a PECVD process and/or an iCVD process, and/or may be formed by a grafting process.

In some embodiments, a sensor may comprise an encasement that is smooth and/or comprises one or more surfaces that is smooth (e.g., one, more than one, or all interior surface(s) of the encasement). The amplitude of the high frequency roughness of the encasement may be less than or equal to 1 micron, less than or equal to 500 nm, less than or equal to 200 nm, less than or equal to 100 nm, less than or equal to 50 nm, less than or equal to 20 nm, less than or equal to 10 nm, less than or equal to 5 nm, less than or equal to 2 nm, less than or equal to 1 nm, less than or equal to 0.5 nm, less than or equal to 0.2 nm, or less than or equal to 0.1 nm. The amplitude of the high frequency roughness of the encasement may be greater than or equal to 0.02 nm, greater than or equal to 0.05 nm, greater than or equal to 0.1 nm, greater than or equal to 0.2 nm, greater than or equal to 0.5 nm, greater than or equal to 1 nm, greater than or equal to 2 nm, greater than or equal to 5 nm, greater than or equal to 10 nm, greater than or equal to 20 nm, greater than or equal to 50 nm, greater than or equal to 100 nm, greater than or equal to 200 nm, or greater than or equal to 500 nm. Combinations of the above-referenced ranges are also possible (e.g., less than or equal to 10 nm and greater than or equal to 0.2 nm, or less than or equal to 1 micron and greater than or equal to 2 nm). Other ranges are also possible. The amplitude of the high frequency roughness may be determined by microscopy.

The high frequency roughness of an encasement may have any suitable period. It should be understood that the amplitude values described above may correspond to high frequency roughnesses with periods inside any of the ranges below. The period of the high frequency roughness of the encasement may be less than or equal to 0.2 nm, greater than or equal to 0.5 nm, greater than or equal to 1 micron, less than or equal to 500 nm, less than or equal to 200 nm, less than or equal to 100 nm, less than or equal to 50 nm, less than or equal to 20 nm, less than or equal to 10 nm, less than or equal to 5 nm, less than or equal to 2 nm, or less than or equal to 1 nm. The period of the high frequency roughness of the encasement may be greater than or equal to 1 nm, greater than or equal to 2 nm, greater than or equal to 5 nm, greater than or equal to 10 nm, greater than or equal to 20 nm, greater than or equal to 50 nm, greater than or equal to 100 nm, greater than or equal to 200 nm, or greater than or equal to 500 nm. Combinations of the above-referenced ranges are also possible (e.g., less than or equal to 200 nm and greater than or equal to 10 nm, or less than or equal to 1 micron and greater than or equal to 2 nm). Other ranges are also possible. In some embodiments, the period of the roughness may be outside the ranges listed above. The period of the high frequency roughness may be determined by microscopy.

When present, the encasement may have any suitable dimensions. In some embodiments, the encasement has a thickness of greater than or equal to 10 nm, greater than or equal to 20 nm, greater than or equal to 50 nm, greater than or equal to 100 nm, greater than or equal to 200 nm, greater than or equal to 500 nm, greater than or equal to 1 micron, greater than or equal to 2 microns, greater than or equal to 5 microns, or greater than or equal to 10 microns. The encasement may have a thickness of less than or equal to 20 microns, less than or equal to 10 microns, less than or equal to 5 microns, less than or equal to 2 microns, less than or equal to 1 micron, less than or equal to 500 nm, less than or equal to 200 nm, less than or equal to 100 nm, less than or equal to 50 nm, or less than or equal to 20 nm. Combinations of the above-referenced ranges are also possible (e.g., greater than or equal to 10 nm and less than or equal to 20 microns, or greater than or equal to 100 nm and less than or equal to 20 microns). Other ranges are also possible. The thickness of the encasement may be determined by microscopy. As used herein, the thickness is of the encasement is the average distance between the outer surface of the encasement and the inner surface of the encasement, when the average is taken over the encasement as a whole. For instance, with reference to FIG. 2A, encasement 104 has thickness 190.

In some embodiments, a sensor comprises an encasement and a mechanical resonator, and the encasement is positioned at a distance from the mechanical resonator of greater than or equal to 100 nm, greater than or equal to 200 nm, greater than or equal to 500 nm, greater than or equal to 1 micron, greater than or equal to 2 microns, greater than or equal to 5 microns, greater than or equal to 10 microns, greater than or equal to 20 microns, greater than or equal to 50 microns, greater than or equal to 100 microns, or greater than or equal to 200 microns. The encasement may be positioned at a distance from the mechanical resonator of less than or equal to 500 microns, less than or equal to 200 microns, less than or equal to 100 microns, less than or equal to 40 microns, less than or equal to 20 microns, less than or equal to 10 microns, less than or equal to 5 microns, less than or equal to 2 microns, less than or equal to 1 micron, less than or equal to 500 nm, or less than or equal to 200 nm. Combinations of the above-referenced ranges are also possible (e.g., greater than or equal to 100 nm and less than or equal to 500 microns, greater than or equal to 100 nm and less than or equal to 40 microns, or greater than or equal to 2 microns and less than or equal to 40 microns). Other ranges are also possible. The distance between the encasement and the mechanical resonator may be determined by microscopy. As used herein, the distance from the encasement to the mechanical resonator is the average distance between the inner surface of the encasement and the outer surface of the mechanical resonator, when the average is taken over the encasement as a whole. For instance, with reference to FIG. 2A, encasement 104 is positioned at distance 192 from mechanical resonator 200.

When present, the encasement may have any suitable minimum radius of curvature. The minimum radius of curvature of the encasement may be greater than or equal to 100 nm, greater than or equal to 200 nm, greater than or equal to 500 nm, greater than or equal to 1 micron, greater than or equal to 2 microns, greater than or equal to 5 microns, greater than or equal to 10 microns, greater than or equal to 20 microns, greater than or equal to 50 microns, greater than or equal to 100 microns, or greater than or equal to 200 microns. The minimum radius of curvature of the encasement may be less than or equal to 500 microns, less than or equal to 200 microns, less than or equal to 100 microns, less than or equal to 50 microns, less than or equal to 20 microns, less than or equal to 10 microns, less than or equal to 5 microns, or less than or equal to 2 microns, less than or equal to 1 microns, less than or equal to 500 nm, or less than or equal to 200 nm. Combinations of the above-referenced ranges are also possible (e.g., greater than or equal to 100 nm and less than or equal to 500 microns). Other ranges are also possible. As used herein, the minimum radius of curvature of the encasement is the radius of curvature of the portion of the encasement with the smallest radius of curvature. The minimum radius of curvature may be determined by microscopy.

In some embodiments, a sensor comprises an encasement with a length of greater than or equal to 10 nm, greater than or equal to 20 nm, greater than or equal to 50 nm, greater than or equal to 100 nm, greater than or equal to 200 nm, greater than or equal to 500 nm, greater than or equal to 1 micron, greater than or equal to 2 microns, greater than or equal to 5 microns, greater than or equal to 10 microns, greater than or equal to 20 microns, greater than or equal to 50 microns, greater than or equal to 100 microns, greater than or equal to 200 microns, greater than or equal to 500 microns, greater than or equal to 1 mm, greater than or equal to 2 mm, greater than or equal to 5 mm, greater than or equal to 10 mm, greater than or equal to 20 mm, or greater than or equal to 50 mm. In some embodiments, the encasement has a length of less than or equal to 100 mm, less than or equal to 50 mm, less than or equal to 20 mm, less than or equal to 10 mm, less than or equal to 5 mm, less than or equal to 2 mm, less than or equal to 1 mm, less than or equal to 550 microns, less than or equal to 500 microns, less than or equal to 200 microns, less than or equal to 100 microns, less than or equal to 50 microns, less than or equal to 10 microns, less than or equal to 5 microns, less than or equal to 2 microns, less than or equal to 1 micron, less than or equal to 500 nm, less than or equal to 200 nm, less than or equal to 100 nm, less than or equal to 50 nm, or less than or equal to 20 nm. Combinations of the above-referenced ranges are also possible (e.g., greater than or equal to 10 nm and less than or equal to 10 mm, greater than or equal to 10 nm and less than or equal to 500 microns, or greater than or equal to 100 nm and less than or equal to 200 microns). Other ranges are also possible. As used herein, the length of the encasement is the length of the longest line that may be drawn from the back surface of the encasement to the front surface of the encasement that is perpendicular to both the front surface of the encasement and the back surface of the encasement. For instance, with reference to FIG. 2A, encasement 104 has length 194.

One or more encasement portions (i.e., portions of the encasement not encasing a sacrificial layer) may have a length of greater than or equal to 10 nm, greater than or equal to 20 nm, greater than or equal to 50 nm, greater than or equal to 100 nm, greater than or equal to 200 nm, greater than or equal to 500 nm, greater than or equal to 1 micron, greater than or equal to 2 microns, greater than or equal to 5 microns, greater than or equal to 10 microns, greater than or equal to 20 microns, greater than or equal to 50 microns, greater than or equal to 100 microns, greater than or equal to 200 microns, greater than or equal to 500 microns, greater than or equal to 1 mm, greater than or equal to 2 mm, greater than or equal to 5 mm, greater than or equal to 10 mm, or greater than or equal to 20 mm. One or more encasement portions may have a length of less than or equal to 50 mm, less than or equal to 20 mm, less than or equal to 10 mm, less than or equal to 5 mm, less than or equal to 2 mm, less than or equal to 1 mm, less than or equal to 550 microns, less than or equal to 500 microns, less than or equal to 200 microns, less than or equal to 100 microns, less than or equal to 50 microns, less than or equal to 10 microns, less than or equal to 5 microns, less than or equal to 2 microns, less than or equal to 1 micron, less than or equal to 500 nm, less than or equal to 200 nm, less than or equal to 100 nm, less than or equal to 50 nm, or less than or equal to 20 nm. Combinations of the above-referenced ranges are also possible (e.g., greater than or equal to 10 nm and less than or equal to 10 mm, greater than or equal to 10 nm and less than or equal to 500 microns, or greater than or equal to 100 nm and less than or equal to 500 microns). Other ranges are also possible. As used herein, the length of an encasement portion (portion of an encasement not encasing a sacrificial layer) is the length of the longest line that may be drawn within the portion of the encasement not encasing a sacrificial layer that is perpendicular to both the front surface of the encasement and the back surface of the encasement. For instance, with reference to FIG. 2G, encasement portion 111A has length 111C and encasement portion 111B has length 111D. With reference to FIG. 2I, encasement portion 111I has length 111K. It should be understood that a length of an encasement portion may extend across one or more openings in the encasement, such as opening 10 in encasement 111, or openings 10 and 18 in encasement 111H.

In some embodiments, a sensor comprises an encasement with a width of greater than or equal to 10 nm, greater than or equal to 20 nm, greater than or equal to 50 nm, greater than or equal to 100 nm, greater than or equal to 200 nm, greater than or equal to 500 nm, greater than or equal to 1 micron, greater than or equal to 2 microns, greater than or equal to 5 microns, greater than or equal to 10 microns, greater than or equal to 20 microns, greater than or equal to 50 microns, greater than or equal to 100 microns, greater than or equal to 200 microns, greater than or equal to 500 microns, greater than or equal to 1 mm, greater than or equal to 2 mm, or greater than or equal to 5 mm. The encasement may have a width of less than or equal to 10 mm, less than or equal to 5 mm, less than or equal to 2 mm, less than or equal to 1 mm, less than or equal to 500 microns, less than or equal to 200 microns, less than or equal to 100 microns, less than or equal to 20 microns, less than or equal to 10 microns, less than or equal to 5 microns, less than or equal to 2 microns, less than or equal to 1 micron, less than or equal to 500 nm, less than or equal to 200 nm, less than or equal to 100 nm, less than or equal to 50 nm, or less than or equal to 20 nm. Combinations of the above-referenced ranges are also possible (e.g., greater than or equal to 10 nm and less than or equal to 10 mm, or greater than or equal to 100 nm and less than or equal to 10 mm). Other ranges are also possible. As used herein, the width of the encasement is the length of the longest line that may be drawn from a first side surface of the encasement to an opposing side surface of the encasement that is perpendicular to the first side surface and the opposing side surface. For instance, with reference to FIG. 2E, encasement 110 has width 196.

One or more encasement portions (i.e., portions of the encasement not encasing a sacrificial layer) may have a width of greater than or equal to 10 nm, greater than or equal to 20 nm, greater than or equal to 50 nm, greater than or equal to 100 nm, greater than or equal to 200 nm, greater than or equal to 500 nm, greater than or equal to 1 micron, greater than or equal to 2 microns, greater than or equal to 5 microns, greater than or equal to 10 microns, greater than or equal to 20 microns, greater than or equal to 100 microns, greater than or equal to 200 microns, greater than or equal to 500 microns, greater than or equal to 1 mm, greater than or equal to 2 mm, or greater than or equal to 5 mm. One or more encasement portions (i.e., portions of the encasement not encasing a sacrificial layer) may have a width of less than or equal to 10 mm, less than or equal to 5 mm, less than or equal to 2 mm, less than or equal to 1 mm, less than or equal to 500 microns, less than or equal to 200 microns, less than or equal to 100 microns, less than or equal to 20 microns, less than or equal to 10 microns, less than or equal to 5 microns, less than or equal to 2 microns, less than or equal to 1 micron, less than or equal to 500 nm, less than or equal to 200 nm, less than or equal to 100 nm, less than or equal to 50 nm, or less than or equal to 20 nm. Combinations of the above-referenced ranges are also possible (e.g., greater than or equal to 10 nm and less than or equal to 10 mm, or greater than or equal to 100 nm and less than or equal to 10 mm). Other ranges are also possible. As used herein, the width of an encasement portion (portion of an encasement not encasing a sacrificial layer) is the length of the longest line that may be drawn from a first side surface of the encasement to an opposing side surface of the encasement that is perpendicular to the first side surface and the opposing side surface and does not pass through a sacrificial layer. For instance, with reference to FIG. 2H, encasement portion 111E has width 111F. With reference to FIG. 2J, encasement portion 111I has width 111L. It should be understood that a width of an encasement portion may extend across one or more openings in the encasement, such as opening 18 in encasement 111H.

When present, the encasement may comprise any suitable material(s). The encasement may comprise one or more of a glass, a plastic, an insulating material, a semiconducting material, a conductive material, and a metal. Non-limiting examples of suitable glasses include amorphous silicon nitride, amorphous silicon dioxide, amorphous aluminum oxide, and amorphous zinc oxide. Non-limiting examples of suitable plastics include polyesters, polyethylene, polyvinyl chloride, polypropylene, polyacrylics, polycellulosics, polycarbonates, polystyrenes, polyamides, polyacetonitriles, polymethlamethacrylate, polyxylylenes, cellulose acetate butyrate, glycol modified polyethylene terphthalate, and styrene butadiene copolymer. Non-limiting examples of suitable semiconducting materials include silicon nitride, silicon dioxide, diamond, and aluminum oxide. Non-limiting examples of suitable conductive materials include amorphous carbon, indium tin oxide (ITO), aluminum zinc oxide (AZO), and indium cadmium oxide. Non-limiting examples of suitable metals include gold, silver, platinum, aluminum, titanium, chromium, titanium nitride, and copper.

As described above, certain embodiments are directed to sensors comprising mechanical resonators. In some embodiments, the sensors described herein may perform particularly well in certain applications and/or may have certain advantageous properties because the mechanical resonator has certain advantageous properties. For example, certain sensors may be well suited for use in an atomic force microscope (e.g., during standard imaging conditions, during non-standard imaging conditions, while exposed to a liquid, while submerged in a liquid). It should also be understood that the sensor may be useful for applications other than atomic force microscopy, such as for use in mass sensors (e.g., in some embodiments, a mass sensor comprises a sensor described herein). Unless otherwise stated, the properties described herein (e.g., properties of the mechanical resonator) should be understood to describe properties in any and/or all possible conditions.

The mechanical resonators described herein may have any suitable quality factor. In some embodiments, the quality factor of the mechanical resonator is greater than or equal to 2, greater than or equal to 5, greater than or equal to 10, greater than or equal to 20, greater than or equal to 50, greater than or equal to 100, greater than or equal to 200, greater than or equal to 500, or greater than equal to 1,000, greater than or equal to 2,000, greater than or equal to 5,000, greater than or equal to 10,000, or greater than or equal to 20,000. In some embodiments, the quality factor of the mechanical resonator is less than or equal to 50,000, less than or equal to 20,000, less than or equal to 10,000, less than or equal to 5,000, less than or equal to 2,000, less than or equal to 1,000, less than or equal to 500, less than or equal to 200, less than or equal to 100, less than or equal to 50, less than or equal to 20, less than or equal to 10, or less than or equal to 5. Combinations of the above-referenced ranges are also possible (e.g., greater than or equal to 2 and less than or equal to 500,000, or greater than or equal to 10 and less than or equal to 2,000). Other ranges are also possible. As used herein, the quality factor is a dimensionless parameter expressing the ratio of the stored energy of an oscillator to the energy dissipation of the oscillator. The quality factor may be measured by performing the following procedure: (1) reflecting a laser from the back side of the mechanical resonator; (2) determining the deflection of the mechanical resonator based on the reflected laser; (3) generating a power spectrum from the thermal motion in the mechanical resonator as determined by the deflection of the mechanical resonator; and (4) fitting a simple harmonic oscillator model to the resonance peak in the generated power spectrum. The quality factor may be determined from the resonance peak.

In some embodiments, a mechanical resonator may have a quality factor when submerged in water that is relatively similar to its quality factor when surrounded by air. The ratio of the quality factor of the mechanical resonator when it is submerged in water to the quality factor of the mechanical resonator when it is surrounded by air may be greater than or equal to 0.02, greater than or equal to 0.05, greater than or equal to 0.1, greater than or equal to 0.2, greater than or equal to 0.5, or greater than or equal to 0.9. The ratio of the quality factor of the mechanical resonator when it is submerged in water to the quality factor of the mechanical resonator when it is surrounded by air may be less than or equal to 1, less than or equal to 0.9, less than or equal to 0.5, less than or equal to 0.2, less than or equal to 0.1, or less than or equal to 0.05. Combinations of the above-referenced ranges are also possible (e.g., greater than or equal to 0.02 and less than or equal to 1). Other ranges are also possible.

When a sensor comprises a mechanical resonator, the mechanical resonator may have any suitable resonant frequency. In some embodiments, the resonant frequency of the mechanical resonator is greater than or equal to 0.1 kHz, greater than or equal to 0.2 kHz, greater than or equal to 0.5 kHz, greater than or equal to 1 kHz, greater than or equal to 2 kHz, greater than or equal to 5 kHz, greater than or equal to 10 kHz, greater than or equal to 20 kHz, greater than or equal to 50 kHz, greater than or equal to 100 kHz, greater than or equal to 200 kHz, greater than or equal to 500 kHz, greater than or equal to 1,000 kHz, greater than or equal to 2,000 kHz, greater than or equal to 5,000 kHz, greater than or equal to 10,000 kHz, greater than or equal to 20,000 kHz, or greater than or equal to 50,000 kHz. In some embodiments, the resonant frequency of the mechanical resonator is less than or equal to 100,000 kHz, less than or equal to 50,000 kHz, less than or equal to 20,000 kHz, less than or equal to 10,000 kHz, less than or equal to 5,000 kHz, less than or equal to 2,000 kHz, less than or equal to 1,000 kHz, less than or equal to 500 kHz, less than or equal to 200 kHz, less than or equal to 100 kHz, less than or equal to 50 kHz, less than or equal to 20 kHz, less than or equal to 10 kHz, less than or equal to 5 kHz, less than or equal to 2 kHz, less than or equal to 1 kHz, less than or equal to 0.5 kHz, or less than or equal to 0.2 kHz. Combinations of the above-referenced ranges are also possible (e.g., greater than or equal to 0.1 kHz and less than or equal to 100,000 kHz, or greater than or equal to 10 kHz and less than or equal to 10,000 kHz). Other ranges are also possible. For resonant frequencies less than 1 MHz, the resonant frequency may be measured by performing the following procedure: (1) reflecting a laser from the back side of the mechanical resonator; (2) determining the deflection of the mechanical resonator based on the reflected laser; (3) generating a power spectrum from the thermal motion in the mechanical resonator as determined by the deflection of the mechanical resonator; and (4) fitting a simple harmonic oscillator model to the resonance peak in the generated power spectrum. The resonant frequency may be determined from the resonance peak. For resonant frequencies between 0.1 kHz and 10,000 kHz, the resonant frequency may be measured by performing the following procedure: (1) reflecting a laser from the back side of the mechanical resonator; (2) determining the deflection of the mechanical resonator based on the reflected laser; (3) exciting mechanical motion of the resonator either through mechanically moving the chip (shaking) or by electrically exciting the resonator through a piezo electric effect, (4) sweeping the excitation frequency, and (5) identifying the resonance through its enhancement of the amplitude of oscillation. For resonant frequencies greater than 100 kHz, the resonant frequency may be measure by (1) measuring the electrical impedance of a circuit that contains the resonator as one of the elements. (2) exciting mechanical motion of the resonator by electrically exciting the resonator through a piezo electric effect, (3) sweeping the excitation frequency, and (5) identifying the resonance through the modulation of the electrical impedance of the circuit near the resonance.

In some embodiments, a mechanical resonator may have a resonance frequency that remains relatively constant after submersion of the sensor in a liquid (e.g., water). The resonance frequency of the mechanical resonator after submersion in the liquid may be, for an extended length of time, relatively close to its resonance frequency prior to submersion in the liquid and/or relatively close to its resonance frequency directly after submersion in the liquid. For example, the resonance frequency of the mechanical resonator may remain relatively constant (e.g., close to its value prior to submersion in the liquid, close to its value directly after submersion in the liquid) for a typical duration of the use of the sensor (e.g., for a typical AFM imaging session, for a typical amount of time to form an AFM image, etc.). The resonance frequency of the mechanical resonator after submersion in the liquid may be within 10% of its resonance frequency prior to submersion in the liquid for greater than or equal to 10 minutes after submersion in the liquid, greater than or equal to 20 minutes after submersion in the liquid, greater than or equal to 30 minutes after submersion in the liquid, greater than or equal to 40 minutes after submersion in the liquid, greater than or equal to 50 minutes after submersion in the liquid, greater than or equal to 60 minutes after submersion in the liquid, greater than or equal to 120 minutes after submersion in the liquid, greater than or equal to 2 hours after submersion in the liquid, greater than or equal to 4 hours after submersion in the liquid, greater than or equal to 8 hours after submersion in the liquid, greater than or equal to 12 hours after submersion in the liquid, greater than or equal to 16 hours after submersion in the liquid, or greater than or equal to 20 hours after submersion in the liquid. The resonance frequency of the mechanical resonator after submersion in the liquid may be within 10% of its resonance frequency prior to submersion in the liquid for less than or equal to 24 hours after submersion in the liquid, less than or equal to 20 hours after submersion in the liquid, less than or equal to 16 hours after submersion in the liquid, less than or equal to 12 hours after submersion in the liquid, less than or equal to 8 hours after submersion in the liquid, less than or equal to 4 hours after submersion in the liquid, less than or equal to 2 hours after submersion in the liquid, less than or equal to 120 minutes after submersion in the liquid, less than or equal to 60 minutes after submersion in the liquid, less than or equal to 50 minutes after submersion in the liquid, less than or equal to 40 minutes after submersion in the liquid, less than or equal to 30 minutes after submersion in the liquid, or less than or equal to 20 minutes after submersion in the liquid. Combinations of the above-referenced ranges are also possible (e.g., greater than or equal to 10 minutes after submersion in the liquid and less than or equal to 24 hours after submersion in the liquid, or greater than or equal to 10 minutes after submersion in the liquid and less than or equal to 120 minutes after submersion in the liquid). Other ranges are also possible.

When a sensor comprises a mechanical resonator, the mechanical resonator may have any suitable stiffness. In some embodiments, the stiffness of the mechanical resonator is greater than or equal to 0.01 N/m, greater than or equal to 0.02 N/m, greater than or equal to 0.05 N/m, greater than or equal to 0.1 N/m, greater than or equal to 0.2 N/m, greater than or equal to 0.5 N/m, greater than or equal to 1 N/m, greater than or equal to 2 N/m, greater than or equal to 5 N/m, greater than or equal to 10 N/m, greater than or equal to 20 N/m, greater than or equal to 50 N/m, greater than or equal to 100 N/m, greater than or equal to 200 N/m, or greater than or equal to 500 N/m. The stiffness of the mechanical resonator may be less than or equal to 1,000 N/m, less than or equal to 500 N/m, less than or equal to 200 N/m, less than or equal to 100 N/m, less than or equal to 50 N/m, less than or equal to 20 N/m, less than or equal to 10 N/m, less than or equal to 5 N/m, less than or equal to 2 N/m, less than or equal to 1 N/m, less than or equal to 0.5 N/m, less than or equal to 0.2 N/m, less than or equal to 0.1 N/m, less than or equal to 0.05 N/m, or less than or equal to 0.02 N/m. Combinations of the above-referenced ranges are also possible (e.g., greater than or equal to 0.01 N/m and less than or equal to 1,000 N/m, or greater than or equal to 0.5 N/m and less than or equal to 100 N/m). Other ranges are also possible. For resonator stiffness less than 100 N/m, the stiffness may be measured by performing the following procedure: (1) reflecting a laser from the back side of the mechanical resonator; (2) determining the deflection of the mechanical resonator based on the reflected laser and scaling for displacement in units of length; (3) generating a power spectrum from the thermal motion in the mechanical resonator as determined by the deflection of the mechanical resonator; (4) fitting a simple harmonic oscillator model to the resonance peak in the generated power spectrum; and (5) the stiffness may be determined from the area under the curve fitting the resonance peak, calculating the scalar of the simple harmonic oscillator model and calculating stiffness from the equipartition theorem, or the Sadar method. Also, when the mechanical resonator comprises a cantilever, the preferred method to calculate stiffness is the Sader method. In the Sader method, the dimensions of the mechanical resonator are measured using microscopy, and the resonance frequency and the quality factor of the mechanical resonator are determined from the thermal noise spectrum. For resonator stiffness greater than 0.01 N/m, the stiffness may be measured by performing the following procedure: (1) A calibration spring is pressed against the resonator while recording the reference spring deflection and total distance moved toward the resonator. (2) The force applied to the resonator is the deflection of the reference spring times its spring constant. (3) the deflection of the resonator is the difference between the total distance moved toward the resonator and the reference spring deflection. (4) the resonator spring constant is the force applied to the resonator divided by the displacement of the resonator.

When present, the mechanical resonator may have any suitable dimensions. The thickness of the mechanical resonator may be greater than or equal to 10 nm, greater than or equal to 20 nm, greater than or equal to 50 nm, greater than or equal to 100 nm, greater than or equal to 200 nm, greater than or equal to 500 nm, greater than or equal to 1 micron, greater than or equal to 2 microns, greater than or equal to 5 microns, greater than or equal to 10 microns, greater than or equal to 20 microns, or greater than or equal to 50 microns. The thickness of the mechanical resonator may be less than or equal to 100 microns, less than or equal to 50 microns, less than or equal to 20 microns, less than or equal to 10 microns, less than or equal to 5 microns, less than or equal to 2 microns, less than or equal to 1 micron, less than or equal to 500 nm, less than or equal to 200 nm, less than or equal to 100 nm, less than or equal to 50 nm, or less than or equal to 20 nm. Combinations of the above-referenced ranges are also possible (e.g., greater than or equal to 10 nm and less than or equal to 100 microns, greater than or equal to 10 nm and less than or equal to 20 microns, or greater than or equal to 100 nm and less than or equal to 20 microns). Other ranges are also possible. The thickness of the mechanical resonator may be determined by microscopy. As used herein, the thickness of the mechanical resonator is the length of the longest line that may be drawn from a top surface of the mechanical resonator to an opposing bottom surface of the mechanical resonator that is perpendicular to the top surface and to the opposing bottom surface. For instance, with reference to FIG. 1A, mechanical resonator 200 has thickness 290.

In some embodiments, a sensor may comprise a mechanical resonator with a length of greater than or equal to 10 nm, greater than or equal to 20 nm, greater than or equal to 50 nm, greater than or equal to 100 nm, greater than or equal to 200 nm, greater than or equal to 500 nm, greater than or equal to 1 micron, greater than or equal to 2 microns, greater than or equal to 5 microns, greater than or equal to 10 microns, greater than or equal to 20 microns, greater than or equal to 50 microns, greater than or equal to 100 microns, greater than or equal to 200 microns, or greater than or equal to 500 microns. The length of the mechanical resonator may be less than or equal to 1 mm, less than or equal to 500 microns, less than or equal to 200 microns, less than or equal to 100 microns, less than or equal to 50 microns, less than or equal to 20 microns, less than or equal to 10 microns, less than or equal to 5 microns, less than or equal to 2 microns, less than or equal to 1 micron, less than or equal to 100 nm, less than or equal to 50 nm, or less than or equal to 20 nm. Combinations of the above-referenced ranges are also possible (e.g., greater than or equal to 10 nm and less than or equal to 1 mm, greater than or equal to 10 nm and less than or equal to 500 microns, or greater than or equal to 100 nm and less than or equal to 500 microns). Other ranges are also possible. The length of the mechanical resonator may be determined by microscopy. As used herein, the length of the mechanical resonator is the length of the longest line that may be drawn from the surface of the mechanical resonator farthest from the front surface of the encasement (e.g., the surface of the mechanical resonator attached to a chip, when a chip is present) to an opposing surface of the mechanical resonator closest to the front surface of the encasement that is perpendicular to the surface of the mechanical resonator farthest from the front surface of the encasement and to the opposing surface of the mechanical resonator closest to the front surface of the encasement. The position of the surface of the mechanical resonator adjacent the chip, as used herein, refers to the surface at which the displacement of the mechanical resonator is less than 0.1% of the displacement of the surface of the mechanical resonator closest to the front surface of the encasement when force is applied to the mechanical resonator to displace the surface of the mechanical resonator closest to the front surface of the encasement from equilibrium. For instance, with reference to FIG. 1A, mechanical resonator 200 has length 292.

In some embodiments, a sensor may comprise a mechanical resonator with a width of greater than or equal to 10 nm, greater than or equal to 20 nm, greater than or equal to 50 nm, greater than or equal to 100 nm, greater than or equal to 200 nm, greater than or equal to 500 nm, greater than or equal to 1 micron, greater than or equal to 2 microns, greater than or equal to 5 microns, greater than or equal to 10 microns, greater than or equal to 20 microns, greater than or equal to 50 microns, greater than or equal to 100 microns, greater than or equal to 200 microns, or greater than or equal to 500 microns. The width of the mechanical resonator may be less than or equal to 500 microns, less than or equal to 200 microns, less than or equal to 100 microns, less than or equal to 50 microns, less than or equal to 20 microns, less than or equal to 10 microns, less than or equal to 5 microns, less than or equal to 2 microns, less than or equal to 1 micron, less than or equal to 500 nm, less than or equal to 200 nm, less than or equal to 100 nm, less than or equal to 50 nm, or less than or equal to 20 nm. Combinations of the above-referenced ranges are also possible (e.g., greater than or equal to 10 nm and less than or equal to 500 microns, greater than or equal to 10 nm and less than or equal to 200 microns, or greater than or equal to 100 nm and less than or equal to 200 microns). Other ranges are also possible. The width of the mechanical resonator may be determined by microscopy. As used herein, the width of the mechanical resonator is the length of the longest line that may be drawn from a first side surface of the mechanical resonator to an opposing side surface of the mechanical resonator that is perpendicular to the first side surface and the opposing side surface. For instance, with reference to FIG. 1C, mechanical resonator 200 has width 94.

When present, the mechanical resonator may comprise any suitable material(s). The mechanical resonator may comprise one or more of a glass, a plastic, an insulating material, a semiconducting material, a piezoelectric material, a piezoresistive material, a conductive material, and a metal. Non-limiting examples of suitable glasses include amorphous silicon nitride, amorphous silicon dioxide, amorphous aluminum oxide, and amorphous zinc oxide. Non-limiting examples of suitable plastics include polyesters, polyethylene, polyvinyl chloride, polypropylene, polyacrylics, polycellulosics, polycarbonates, polystyrenes, polyamides, polyacetonitriles, polymethlamethacrylate, polyxylylenes, cellulose acetate butyrate, glycol modified polyethylene terphthalate, and styrene butadiene copolymer. Non-limiting examples of suitable insulating materials include silicon nitride, silicon dioxide, diamond, and aluminum oxide. Non-limiting examples of suitable semiconducting materials include silicon, silicon doped with boron, silicon doped with phosphorus, silicon doped with arsenic, silicon doped with gallium, gallium arsenide, doped diamond, amorphous carbon, zinc oxide, and indium gallium zinc oxide. Non-limiting examples of suitable piezoelectric materials include lead zirconate titanate (PZT), quartz, and lead titanate. Non-limiting examples of suitable piezoresistive materials include silicon, silicon doped with boron, silicon doped with phosphorus, silicon doped with arsenic, and silicon doped with gallium. Non-limiting examples of suitable conductive materials include amorphous carbon, indium tin oxide (ITO), aluminum zinc oxide (AZO), and indium cadmium oxide. Non-limiting examples of suitable metals include gold, silver, platinum, aluminum, titanium, chromium, titanium nitride, and copper.

As described above, certain embodiments are directed to sensors comprising probes. When present, the probe may have any suitable dimensions. In some embodiments, the probe has a height of greater than or equal to 100 nm, greater than or equal to 200 nm, greater than or equal to 500 nm, greater than or equal to 1 micron, greater than or equal to 2 microns, greater than or equal to 5 microns, greater than or equal to 10 microns, greater than or equal to 20 microns, greater than or equal to 50 microns, greater than or equal to 100 microns, or greater than or equal to 200 microns. In some embodiments, the probe has a height of less than or equal to 500 microns, less than or equal to 200 microns, less than or equal to 100 microns, less than or equal to 50 microns, less than or equal to 20 microns, less than or equal to 10 microns, less than or equal to 5 microns, less than or equal to 2 microns, less than or equal to 1 micron, less than or equal to 500 nm, or less than or equal to 200 nm. Combinations of the above-referenced ranges are also possible (e.g., greater than or equal to 100 nm and less than or equal to 500 microns). Other ranges are also possible. The height of the probe may be determined by microscopy. As used herein, the height of the probe is the length of the longest line that may be drawn perpendicular to the bottom surface of the mechanical resonator to the end of the probe. For instance, with reference to FIG. 1A, probe 300 has height 390.

In some embodiments, a sensor may comprise an encasement and a probe that protrudes beyond the encasement. The probe may protrude beyond the encasement for a distance of greater than or equal to 100 nm, greater than or equal to 200 nm, greater than or equal to 500 nm, greater than or equal to 1 micron, greater than or equal to 2 microns, greater than or equal to 5 microns, greater than or equal to 10 microns, greater than or equal to 20 microns, or greater than or equal to 50 microns. The probe may protrude beyond the encasement for a distance of less than or equal to 100 microns, less than or equal to 50 microns, less than or equal to 20 microns, less than or equal to 10 microns, less than or equal to 5 microns, less than or equal to 2 microns, less than or equal to 1 micron, less than or equal to 500 nm, or less than or equal to 200 nm. Combinations of the above-referenced ranges are also possible (e.g., greater than or equal to 100 nm and less than or equal to 100 microns). Other ranges are also possible. The length that the probe protrudes beyond the encasement may be determined by microscopy. As used herein, the distance the probe protrudes beyond the encasement is the length of the longest line that may be drawn perpendicular to the bottom surface of the encasement from the portion of the probe furthest from the encasement to the bottom surface of the encasement. For instance, with reference to FIG. 1A, probe 300 protrudes beyond encasement 100 for distance 392.

In some embodiments, a sensor may comprise a probe and a mechanical resonator, and the ratio of the height of the probe to the width of the mechanical resonator may have an advantageous value. The ratio of the height of the probe to the width of the mechanical resonator may be greater than or equal to 0.1, greater than or equal to 0.2, greater than or equal to 0.5, greater than or equal to 1, greater than or equal to 2, or greater than or equal to 5. The ratio of the height of the probe to the width of the mechanical resonator may be less than or equal to 10, less than or equal to 5, less than or equal to 2, less than or equal to 1, less than or equal to 0.5, or less than or equal to 0.2. Combinations of the above-referenced ranges are also possible (e.g., greater than or equal to 0.1 and less than or equal to 10). Other ranges are also possible.

When present, the probe may comprise any suitable material(s). The probe may comprise one or more of a glass, a plastic, an insulating material, a semiconducting material, a conductive material, a metal, and a carbonanceous material. Non-limiting examples of suitable glasses include amorphous silicon nitride, amorphous silicon dioxide, amorphous aluminum oxide, and amorphous zinc oxide. Non-limiting examples of suitable plastics include polyesters, polyethylene, polyvinyl chloride, polypropylene, polyacrylics, polycellulosics, polycarbonates, polystyrenes, polyamides, polyacetonitriles, polymethlamethacrylate, polyxylylenes, cellulose acetate butyrate, glycol modified polyethylene terphthalate, and styrene butadiene copolymer. Non-limiting examples of suitable insulating materials include silicon nitride, silicon dioxide, diamond, and aluminum oxide. Non-limiting examples of suitable semiconducting materials include silicon, silicon doped with boron, silicon doped with phosphorus, silicon doped with arsenic, silicon doped with gallium, gallium arsenide, doped diamond, amorphous carbon, zinc oxide, and indium gallium zinc oxide. Non-limiting examples of suitable conductive materials include amorphous carbon, indium tin oxide (ITO), aluminum zinc oxide (AZO), and indium cadmium oxide. Non-limiting examples of suitable metals include gold, silver, platinum, aluminum, titanium, chromium, titanium nitride, and copper. Non-limiting examples of suitable carbonaceous materials include multi-walled carbon nanotubes, single-walled carbon nanotubes, and amorphous carbon formed by electron beam deposition. In some embodiments, and amorphous carbon formed by electron beam deposition may be present at the apex of the probe.

As described above, certain embodiments are directed to sensors comprising chips. When present the chip may have any suitable dimension. The chip may have a width and/or a length of greater than or equal to 0.5 mm, greater than or equal to 0.75 mm, greater than or equal to 1 mm, greater than or equal to 2 mm, greater than or equal to 5 mm, or greater than or equal to 7.5 mm. The chip may have a width and/or a length of less than or equal to 10 mm, less than or equal to 7.5 mm, less than or equal to 5 mm, less than or equal to 2 mm, less than or equal to 1 mm, or less than or equal to 0.75 mm. Combinations of the above-referenced ranges are also possible (e.g., greater than or equal to 0.5 mm and less than or equal to 10 mm). In some embodiments, a chip may be a rectangle with side lengths 1.6 mm and 3.4 mm.

When present, the chip may comprise any suitable material(s). The chip may comprise one or more of a glass, a plastic, an insulating material, a semiconducting material, a piezoelectric material, a piezoresistive material, a conductive material, and a metal. Non-limiting examples of suitable glasses include amorphous silicon nitride, amorphous silicon dioxide, amorphous aluminum oxide, and amorphous zinc oxide. Non-limiting examples of suitable plastics include polyesters, polyethylene, polyvinyl chloride, polypropylene, polyacrylics, polycellulosics, polycarbonates, polystyrenes, polyamides, polyacetonitriles, polymethlamethacrylate, polyxylylenes, cellulose acetate butyrate, glycol modified polyethylene terphthalate, and styrene butadiene copolymer. Non-limiting examples of suitable insulating materials include silicon nitride, silicon dioxide, diamond, and aluminum oxide. Non-limiting examples of suitable semiconducting materials include silicon, silicon doped with boron, silicon doped with phosphorus, silicon doped with arsenic, silicon doped with gallium, gallium arsenide, doped diamond, amorphous carbon, zinc oxide, and indium gallium zinc oxide. Non-limiting examples of suitable piezoelectric materials include lead zirconate titanate (PZT), quartz, and lead titanate. Non-limiting examples of suitable piezoresistive materials include silicon, silicon doped with boron, silicon doped with phosphorus, silicon doped with arsenic, and silicon doped with gallium. Non-limiting examples of suitable conductive materials include amorphous carbon, indium tin oxide (ITO), aluminum zinc oxide (AZO), and indium cadmium oxide. Non-limiting examples of suitable metals include gold, silver, platinum, aluminum, titanium, chromium, titanium nitride, and copper.

A simple, mask-less, fabrication technique may be used to fabricate sensors as described herein. A commercially available AFM cantilever may be used for one or more portions of a sensor described herein, such as a chip, a resonator, and/or a probe. In some embodiments, a cantilever is entirely coated with a sacrificial layer. As described above, this sacrificial layer may define a gap between the between the encasement and the cantilever/resonator. A second layer may be deposited on the sacrificial layer to build up the encasement. Then, openings may be formed in the encasement and the sacrificial layer may be selectively removed, exposing the probe and the cantilever/resonator.

For example, silicon dioxide that functions as a sacrificial layer may be deposited on a silicon cantilever using a plasma enhanced chemical vapor deposition (PECVD) process to uniformly coat the silicon cantilever. Silicon nitride may be deposited on the silicon dioxide to uniformly coat the silicon dioxide. A focused ion beam (FIB) may be used to cut one or more openings (e.g., one or more of the openings described herein). A portion of the sacrificial silicon dioxide layer is released by vapor etching using hydrofluoric acid, exposing a resonator portion of the cantilever. In some embodiments, a hydrophobic coating may be applied to the probe to aid in preventing water from entering into the opening.

As described above, in certain embodiments the sensor may be suitable for use as an atomic force microscopy sensor. When used as an atomic force microscopy sensor, the position of the sensor in space (e.g., as a function of time) and components thereof (e.g., a mechanical resonator, a probe, etc.) may be determined using standard techniques employed during atomic force microscopy imaging. These techniques are described in detail in U.S. Pat. No. 9,229,028. For instance, in certain cases, optical beam deflection measurements, interferometric measurements, optical beam diffraction measurements, capacitive measurements, piezoelectric measurements, and/or piezoresistive measurements may be employed to determine the position of the mechanical resonator.

The following examples are intended to illustrate certain embodiments of the present invention, but do not exemplify the full scope of the invention.

### EXAMPLE 1

In this Example, a sensor comprising an encasement including more than one openings was compared to a sensor comprising an encasement including only a single opening surrounding the probe.

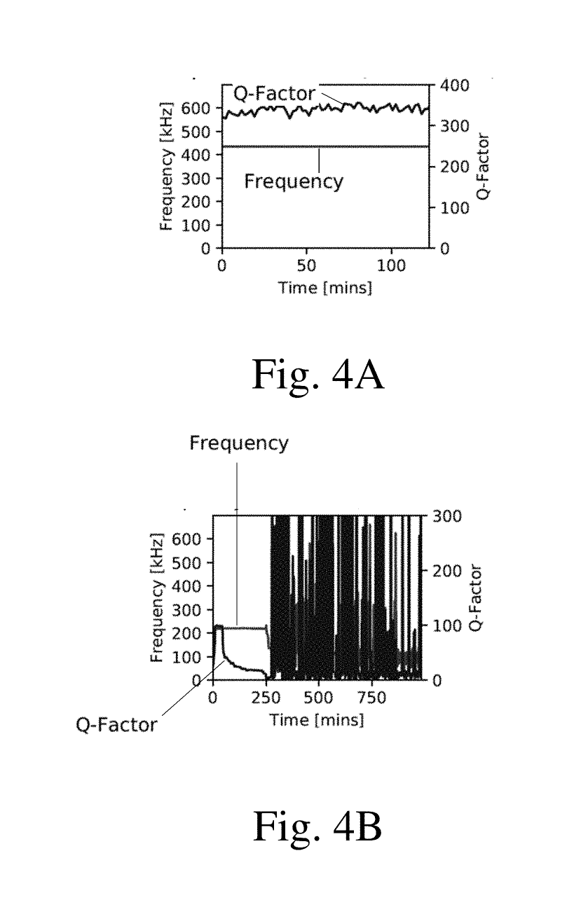

The sensor comprising the encasement with multiple openings performed better than the sensor comprising the encasement including only a single opening. It maintained a stable frequency and quality factor for a period of time of greater than 100 minutes after submersion in water (see FIG. 4A), while the quality factor of the sensor comprising the encasement including only a single opening began to decay significantly after a period of approximately 50 minutes (see FIG. 4B).

While several embodiments of the present invention have been described and illustrated herein, those of ordinary skill in the art will readily envision a variety of other means and/or structures for performing the functions and/or obtaining the results and/or one or more of the advantages described herein, and each of such variations and/or modifications is deemed to be within the scope of the present invention. More generally, those skilled in the art will readily appreciate that all parameters, dimensions, materials, and configurations described herein are meant to be exemplary and that the actual parameters, dimensions, materials, and/or configurations will depend upon the specific application or applications for which the teachings of the present invention is/are used. Those skilled in the art will recognize, or be able to ascertain using no more than routine experimentation, many equivalents to the specific embodiments of the invention described herein. It is, therefore, to be understood that the foregoing embodiments are presented by way of example only and that, within the scope of the appended claims and equivalents thereto, the invention may be practiced otherwise than as specifically described and claimed. The present invention is directed to each individual feature, system, article, material, kit, and/or method described herein. In addition, any combination of two or more such features, systems, articles, materials, kits, and/or methods, if such features, systems, articles, materials, kits, and/or methods are not mutually inconsistent, is included within the scope of the present invention.

All definitions, as defined and used herein, should be understood to control over dictionary definitions, definitions in documents incorporated by reference, and/or ordinary meanings of the defined terms.

The indefinite articles “a” and “an,” as used herein in the specification and in the claims, unless clearly indicated to the contrary, should be understood to mean “at least one.”

The phrase “and/or,” as used herein in the specification and in the claims, should be understood to mean “either or both” of the elements so conjoined, i.e., elements that are conjunctively present in some cases and disjunctively present in other cases. Multiple elements listed with “and/or” should be construed in the same fashion, i.e., “one or more” of the elements so conjoined. Other elements may optionally be present other than the elements specifically identified by the “and/or” clause, whether related or unrelated to those elements specifically identified. Thus, as a non-limiting example, a reference to “A and/or B”, when used in conjunction with open-ended language such as “comprising” can refer, in one embodiment, to A only (optionally including elements other than B); in another embodiment, to B only (optionally including elements other than A); in yet another embodiment, to both A and B (optionally including other elements); etc.

As used herein in the specification and in the claims, “or” should be understood to have the same meaning as “and/or” as defined above. For example, when separating items in a list, “or” or “and/or” shall be interpreted as being inclusive, i.e., the inclusion of at least one, but also including more than one, of a number or list of elements, and, optionally, additional unlisted items. Only terms clearly indicated to the contrary, such as “only one of” or “exactly one of,” or, when used in the claims, “consisting of,” will refer to the inclusion of exactly one element of a number or list of elements. In general, the term “or” as used herein shall only be interpreted as indicating exclusive alternatives (i.e. “one or the other but not both”) when preceded by terms of exclusivity, such as “either,” “one of,” “only one of,” or “exactly one of.” “Consisting essentially of,” when used in the claims, shall have its ordinary meaning as used in the field of patent law.

As used herein in the specification and in the claims, the phrase “at least one,” in reference to a list of one or more elements, should be understood to mean at least one element selected from any one or more of the elements in the list of elements, but not necessarily including at least one of each and every element specifically listed within the list of elements and not excluding any combinations of elements in the list of elements. This definition also allows that elements may optionally be present other than the elements specifically identified within the list of elements to which the phrase “at least one” refers, whether related or unrelated to those elements specifically identified. Thus, as a non-limiting example, “at least one of A and B” (or, equivalently, “at least one of A or B,” or, equivalently “at least one of A and/or B”) can refer, in one embodiment, to at least one, optionally including more than one, A, with no B present (and optionally including elements other than B); in another embodiment, to at least one, optionally including more than one, B, with no A present (and optionally including elements other than A); in yet another embodiment, to at least one, optionally including more than one, A, and at least one, optionally including more than one, B (and optionally including other elements); etc.

It should also be understood that, unless clearly indicated to the contrary, in any methods claimed herein that include more than one step or act, the order of the steps or acts of the method is not necessarily limited to the order in which the steps or acts of the method are recited.

In the claims, as well as in the specification above, all transitional phrases such as “comprising,” “including,” “carrying,” “having,” “containing,” “involving,” “holding,” “composed of,” and the like are to be understood to be open-ended, i.e., to mean including but not limited to. Only the transitional phrases “consisting of” and “consisting essentially of” shall be closed or semi-closed transitional phrases, respectively, as set forth in the United States Patent Office Manual of Patent Examining Procedures, Section 2111.03.

What is claimed is:

1. A sensor, comprising:
a mechanical resonator;
a probe attached to the mechanical resonator; and
an encasement encasing the mechanical resonator, wherein the encasement comprises:
a first opening through which the probe protrudes; and
a second opening.

2. A sensor as in claim 1, wherein the second opening is in fluidic communication with the first opening.

3-6. (canceled)

7. A sensor as in claim 1, wherein the mechanical resonator is attached to a chip.

8. A sensor as in claim 7, wherein the encasement encases the chip.

9. A sensor as in claim 1, wherein a largest cross-sectional dimension of the second opening is greater than a largest cross-sectional dimension of the first opening.

10-17. (canceled)

18. A sensor as claim 1, wherein the second opening is positioned on the same surface of the encasement as the first opening.

19. (canceled)

20. A sensor as in any claim 1, wherein the second opening is positioned at a bottom surface of the encasement.

21-22. (canceled)

23. A sensor as in claim 8, wherein the second opening is positioned beneath a portion of the chip.

24. A sensor as in claim 1, wherein the encasement further comprises a third opening that can be multiple openings.

25-28. (canceled)

29. A sensor as in claim 24, wherein the third opening is in fluidic communication with the first opening.

30. A sensor as in claim 24, wherein the third opening is positioned on the same surface of the encasement as the first opening.

31. A sensor as in claim 24, wherein the third opening is positioned on a different surface of the encasement as the first opening.

32. A sensor as in claim 24, wherein the mechanical resonator is attached to a chip, the encasement encases the chip, and the third opening is positioned beneath a portion of the chip.

33-34. (canceled)

35. A sensor as in claim 1, wherein a fluid is positioned between the encasement and the mechanical resonator.

36. A sensor as in claim 35, wherein the fluid is a gas.

37. (canceled)

38. A sensor as in claim 1, wherein the chip comprises a reservoir in fluid communication with the first opening.

39-48. (canceled)

49. A sensor as in claim 1, wherein the encasement further comprises one or more additional openings comprising an opening on a front surface of the encasement.

50. A sensor as in claim 1, wherein the encasement further comprises one or more additional openings comprising an opening on a side surface of the encasement.

51. A sensor as in claim 1, wherein the encasement further comprises one or more additional openings comprising an opening on a back surface of the encasement.

52-55. (canceled)

56. A sensor as in claim 1, wherein an interior surface of the encasement is hydrophobic or has a hydrophobic coating.

57-61. (canceled)
